(19) United States
(12) Patent Application Publication
(10) Pub. No.: US 2015/0303317 A1
(43) Pub. Date: Oct. 22, 2015

(54) SEMICONDUCTOR SUBSTRATE PROVIDED WITH PASSIVATION FILM AND PRODUCTION METHOD, AND PHOTOVOLTAIC CELL ELEMENT AND PRODUCTION METHOD THEREFOR

(71) Applicant: Hitachi Chemical Company, Ltd., Tokyo (JP)

(72) Inventors: Tooru TANAKA, Ibaraki (JP); Akihiro ORITA, Ibaraki (JP); Takeshi NOJIRI, Ibaraki (JP); Masato YOSHIDA, Ibaraki (JP)

(21) Appl. No.: 14/370,630

(22) PCT Filed: Dec. 28, 2012
(86) PCT No.: PCT/JP2012/084160

§ 371 Date: Jul. 3, 2014

(30) Foreign Application Priority Data
Jan. 6, 2012 (JP) 2012-001653

(51) Int. Cl. H01L 31/0216; C08K 5/56; C09D 101/28; H01L 31/068; H01L 31/18; H01L 31/0224

(52) U.S. Cl. CPC H01L 31/02167; H01L 31/1868; H01L 31/1864; H01L 31/022425; C09D 101/28; H01L 31/068; C08K 5/56

(57) ABSTRACT

The invention provides a method of producing a semiconductor substrate provided with a passivation film, the method including: forming an electrode on a semiconductor substrate; applying a composition for forming a semiconductor substrate passivation film onto a surface, on which the electrode is formed, of the semiconductor substrate to form a composition layer, the composition containing an organic aluminum compound; and heat-treating the composition layer to form a passivation film.

### TECHNICAL FIELD

The present invention relates to a semiconductor substrate provided with a passivation film and a production method therefor as well as a photovoltaic cell element and a production method therefor.

### BACKGROUND ART

Conventional processes for producing a silicon photovoltaic cell element will be described.

A p-type silicon substrate with a textured light-receiving surface for attaining higher efficiency by promoting a light trapping effect is prepared, and then is treated in a mixed gas atmosphere of phosphorus oxychloride (POCl₃), nitrogen, and oxygen at a temperature from 800° C. to 900° C. for several tens of minutes to form uniformly an n-type diffusion layer. By this conventional method, since phosphorus is diffused using a mixed gas, the n-type diffusion layer is formed not only on the light-receiving surface but also on side surfaces and a back surface. Therefore, side etching is performed in order to remove the n-type diffusion layer on the side surfaces. Further, since the n-type diffusion layer on the back surface has to be converted to a p⁺-type diffusion layer, an aluminum paste is coated all over the back surface and sintered to form an aluminum electrode, whereby the n-type diffusion layer is converted to a p⁺-type diffusion layer and at the same time an ohmic contact is established.

However, the aluminum electrode formed from the aluminum paste has a low electric conductivity. Therefore, the aluminum electrode formed on the entire back surface should ordinarily have a thickness of from about 10 μm to 20 μm after sintering in order to lower the sheet resistance. Moreover, since silicon and aluminum are quite different in coefficient of thermal expansion, a large internal stress is generated in a silicon substrate during steps of sintering and cooling, which may give damages in a crystal grain boundary, increase crystal defects, or cause a warp.

To eliminate the above drawback, there is a method in which the coating amount of an aluminum paste is decreased so as to reduce the thickness of a back surface electrode layer. However, when the coating amount of an aluminum paste is decreased, the amount of aluminum diffused from a surface of a p-type silicon semiconductor substrate inward becomes insufficient. As a result, there arises another drawback that a desired Back Surface Field (BSF) effect (an effect of improving the collection efficiency of a generated carrier owing to the presence of a p⁺-type diffusion layer) cannot be achieved and the properties of a photovoltaic cell are impaired.

In this connection, a point contact technique in which an aluminum paste is applied onto a part of a silicon substrate surface to partly form a p⁺ layer and an aluminum electrode has been proposed (e.g. see Japanese Patent No. 3107287).

In a case of a photovoltaic cell having a point contact structure at the opposite side of a light-receiving surface (hereinafter also referred to as “back surface”), the recombination speed of minority carriers at a surface of a part of the back surface other than an aluminum electrode has to be suppressed. For this purpose, a SiO₂ film, etc. have been proposed as a semiconductor substrate passivation film (hereinafter also referred to simply as “passivation film”) for the back surface (e.g. see Japanese Patent Application Laid-Open (JP-A) No. 2004-6565). As a passivation effect by forming such an oxide film, there is an effect of terminating a dangling bond of silicon atoms at the surface of the back surface of a silicon substrate so as to reduce the surface level density which causes a recombination.

As another method for suppressing a recombination of minority carriers, there is a method in which the minority carrier density is reduced by an electric field generated by a fixed charge in a passivation film. Such a passivation effect is called generally as an electric field effect, and an aluminum oxide (Al₂O₃) film or the like has been proposed as a material having a negative fixed charge (e.g. see Japanese Patent No. 4767110).

Such a passivation film is generally formed by a method such as an Atomic Layer Deposition (ALD) method or a Chemical Vapor Deposition (CVD) method (e.g. see Journal of Applied Physics, 104 (2008), 113703). Further, as a simple technique for forming an aluminum oxide film on a semiconductor substrate, a technique by a sol-gel method has been proposed (e.g. see Thin Solid Films, 517 (2009), 6327-6330; and Chinese Physics Letters, 26 (2009), 088102).

### SUMMARY OF INVENTION

### Technical Problem

In order to produce efficiently a photovoltaic cell having a point contact structure, it is desirable that an aluminum electrode in a predetermined pattern is formed on a semiconductor substrate before forming a passivation film, and a passivation film is formed only in a region on the semiconductor substrate in which the aluminum electrode has not been formed. However, it is difficult by an ALD method, a CVD method, or a sol-gel method using a low viscosity solution as described in Journal of Applied Physics, 104 (2008), 113703; Thin Solid Films, 517 (2009), 6327-6330; and Chinese Physics Letters, 26 (2009), 088102 to form directly a passivation film only in a region in which an aluminum electrode has not been formed. Therefore, in the case of the above method, it has been necessary to undergo a complex process that a passivation film is formed once on a semiconductor substrate, the passivation film in a region, in which an electrode is to be formed on the semiconductor substrate in a predetermined pattern, is removed by perforation or etching, and then an electrode is formed on such a cleared part. Such a complex process has been a major obstacle to industrial application.

The present invention is made in view of the above-mentioned problems with an object to provide a method of producing a semiconductor substrate provided with a passivation film, by which a semiconductor substrate passivation film superior in passivation effect can be formed by a simple technique in a desired shape, and a production method of a photovoltaic cell element.

### Solution to Problem

Specific means for achieving the object are as follows.

<1> A method of producing a semiconductor substrate provided with a passivation film, the method comprising:

forming an electrode on a semiconductor substrate;

applying a composition for forming a passivation film onto a surface, on which the electrode is formed, of the semiconductor substrate to form a composition layer, the composition comprising an organic aluminum compound; and

heat-treating the composition layer to form a passivation film.

<2> The method of producing a semiconductor substrate provided with a passivation film according to <1> above, wherein the composition layer formed using the composition for forming a semiconductor substrate passivation film is formed in a region on the semiconductor substrate in which the electrode is not formed.

<3> The method of producing a semiconductor substrate provided with a passivation film according to <1> or <2> above, wherein the formation of the electrode comprises:

applying a composition for forming an electrode onto the semiconductor substrate to form a composition layer for forming an electrode; and

heat-treating the composition layer for forming an electrode.

<4> The method of producing a semiconductor substrate provided with a passivation film according to any one of <1> to <3> above, wherein the composition for forming a passivation film comprises:

a compound represented by the following General Formula (I) as the organic aluminum compound; and

a resin:

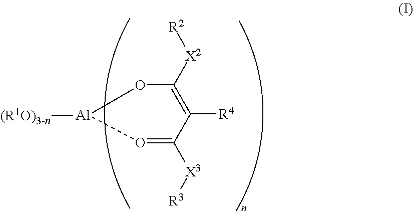

wherein, in General Formula (I), R¹'s each independently represent an alkyl group having 1 to 8 carbon atoms; n represents an integer of from 0 to 3; X² and X³ each independently represent an oxygen atom or a methylene group; and R², R³ and R⁴ each independently represent a hydrogen atom or an alkyl group having 1 to 8 carbon atoms.

<5> The method of producing a semiconductor substrate provided with a passivation film according to <4> above, wherein, in General Formula (I), R¹'s each independently represent an alkyl group having 1 to 4 carbon atoms.

<6> The method of producing a semiconductor substrate provided with a passivation film according to <4> or <5> above, wherein, in General Formula (I), n is an integer of from 1 to 3, and R⁴'s each independently represent a hydrogen atom or an alkyl group having 1 to 4 carbon atoms.

<7> A semiconductor substrate provided with a passivation film produced by the production method according to any one of <1> to <6> above.

<8> A method of producing a photovoltaic cell element, the method comprising:

forming an electrode on at least one layer selected from the group consisting of a p-type layer and an n-type layer of a semiconductor substrate comprising a p-n junction of the p-type layer and the n-type layer;
forming a composition layer by using a composition for forming a semiconductor substrate passivation film on one or both surfaces of the semiconductor substrate on which the electrode is formed, the composition for forming a semiconductor substrate passivation film comprising an organic aluminum compound; and

heat-treating the composition layer to form a passivation film.

<9> The method of producing a photovoltaic cell element according to <8> above, wherein the composition for forming a semiconductor substrate passivation film is applied to a region on the semiconductor substrate in which the electrode is not formed.

<10> The method of producing a photovoltaic cell element according to <8> or <9> above, wherein the formation of an electrode comprises:
applying a composition for forming an electrode onto a semiconductor substrate to form a composition layer for forming an electrode; and

sintering the composition layer for forming an electrode to form an electrode.

<11> The method of producing a photovoltaic cell element according to any one of <8> to <10> above, wherein the composition for forming a semiconductor substrate passivation film comprises: a compound represented by the following General Formula (I) as the organic aluminum compound; and

a resin:

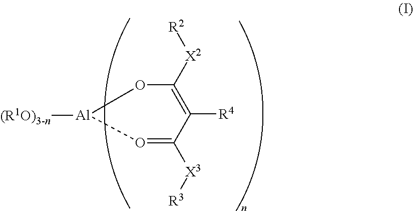

wherein, in General Formula (I), R¹'s each independently represent an alkyl group having 1 to 8 carbon atoms; n represents an integer of from 0 to 3; X² and X³ each independently represent an oxygen atom or a methylene group; R², R³ and R⁴ each independently represent a hydrogen atom or an alkyl group having 1 to 8 carbon atoms.

<12> The method of producing a photovoltaic cell element according to <11> above, wherein, in General Formula (I), R¹'s each independently represent an alkyl group having 1 to 4 carbon atoms.

<13> The method of producing a photovoltaic cell element according to <11> or <12> above, wherein, in General Formula (I), n is an integer of from 1 to 3, and R⁴'s each independently represent a hydrogen atom or an alkyl group having 1 to 4 carbon atoms.

<14> A photovoltaic cell element, produced by the production method according to any one of <8> to <13> above.

### Advantageous Effects of Invention

According to the present invention, a method of producing a semiconductor substrate provided with a passivation film, by which a semiconductor substrate passivation film with a superior passivation effect can be formed into a desired shape by a simple technique, and a production method of a photovoltaic cell element are provided.

### BRIEF DESCRIPTION OF DRAWINGS

FIG. 1 is a schematic cross-sectional view of an example of a production method of a photovoltaic cell element provided with a semiconductor substrate passivation film according to an embodiment of the present invention.

FIG. 2 is a schematic cross-sectional view of another example of a production method of a photovoltaic cell element provided with a semiconductor substrate passivation film according to an embodiment of the present invention.

FIG. 3 is a schematic cross-sectional view of a back contact photovoltaic cell element provided with a semiconductor substrate passivation film according to an embodiment of the present invention.

FIG. 4 is a schematic cross-sectional view of another example of a production method of a photovoltaic cell element provided with a semiconductor substrate passivation film according to an embodiment of the present invention.

FIG. 5 is a schematic cross-sectional view of another example of a production method of a photovoltaic cell element provided with a semiconductor substrate passivation film according to an embodiment of the present invention.

FIG. 6 is a plan view of an example of a screen mask plate for forming an electrode according to an embodiment of the present invention.

### DESCRIPTION OF EMBODIMENTS

The term “step” includes herein not only an independent step, but also a step which may not be clearly separated from another step, insofar as an intended function of the step can be attained. A numerical range expressed by “x to y” includes herein the values of x and y in the range as the minimum and maximum values, respectively. In referring herein to a content of a component in a composition, when plural substances exist corresponding to a component in the composition, the content means, unless otherwise specified, the total amount of the plural substances existing in the composition.

<Production Method of Semiconductor Substrate with Passivation Film>

A method of producing a semiconductor substrate provided with a passivation film according to the invention includes: forming an electrode on a semiconductor substrate; applying a composition for forming a passivation film onto a surface on which the electrode is formed of the semiconductor substrate to form a composition layer, the composition containing an organic aluminum compound; and heat-treating the composition layer to form a passivation film. The production method may include, if necessary, another step.

By applying a composition for forming a passivation film containing an organic aluminum compound to a surface on which an electrode is formed of a semiconductor substrate into a pattern of a desired shape, and heat-treating the same to form a passivation film, a semiconductor substrate provided with a passivation film having a desired shape and being superior in passivation effect can be produced by simple process steps.

By the production method according to the invention, an electrode may be formed on a semiconductor substrate before a passivation film is formed, or an electrode may be formed after a passivation film is formed on a semiconductor substrate at least in a region on the semiconductor substrate, in which a passivation film is not formed. By the production method according to the invention, an electrode is preferably formed on a semiconductor substrate before the formation of a passivation film.

When electrode formation is performed by sintering a composition for forming an electrode, a heat treatment at a temperature higher than a heat treatment temperature for forming a passivation film may be occasionally conducted. In this case, when sintering is conducted for forming an electrode after a passivation film is formed as in a conventional production method of a semiconductor substrate provided with a passivation film, an amorphous aluminum oxide layer, which has been formed as a passivation film, may be changed by the high temperature sintering from an amorphous state to a crystalline state. However, in a case of the production method according to the invention, a passivation film may be formed also after an electrode is formed, and therefore an aluminum oxide layer as a passivation film can be easily kept in an amorphous state superior in passivation effect.

In the present specification, the passivation effect of a semiconductor substrate may be evaluated by performing a measurement of an effective lifetime of a minority carrier in a semiconductor substrate provided with a semiconductor substrate passivation film by a microwave reflectance photoconductivity decay method using an instrument such as WT-2000PVN (manufactured by Semilab Japan K.K.).

In this regard, effective lifetime τ is expressed by the bulk lifetime τ_{b} inside a semiconductor substrate and the surface lifetime τₛ in a surface of a semiconductor substrate according to the following formula (A). Since τₛ becomes large when the surface state density of a semiconductor substrate is small, the effective lifetime τ becomes large. Further, when the generation of defects such as a dangling bond inside a semiconductor substrate is suppressed, the bulk lifetime τ_{b} becomes longer and the effective lifetime τ becomes longer. In other words, by measuring an effective lifetime τ, interface characteristics between a passivation film and a semiconductor substrate and internal characteristics of a semiconductor substrate such as a dangling bond can be evaluated.

1/τ=1/τ_{b}+1/τₛ (A)

In this regard, a longer effective lifetime means a retarded recombination speed of minority carriers. Further, the conversion efficiency can be improved by constructing a photovoltaic cell element provided with a semiconductor substrate having a longer effective lifetime.

There is no particular restriction on a semiconductor substrate to be used in a production method according to the invention, and it may be selected appropriately according to an object from the substrates used ordinarily. There is no particular restriction on the semiconductor substrate, insofar as it is prepared by diffusing (doping) a p-type impurity or an n-type impurity to silicon, germanium, etc. Among others, a silicon substrate is preferable. Meanwhile, a semiconductor substrate may be either a p-type semiconductor substrate or an n-type semiconductor substrate. Especially, from a viewpoint of passivation effect, a surface of a semiconductor substrate, on which a passivation film is to be formed, is preferably a p-type layer. The p-type layer on a semiconductor substrate may be a p-type layer originated from a p-type semiconductor substrate, or formed on an n-type semiconductor substrate or a p-type semiconductor substrate as a p-type diffusion layer or a p⁺-type diffusion layer.

There is no particular restriction on the thickness of the semiconductor substrate, and it may be selected appropriately according to an object. For example, the thickness may be from 50 μm to 1000 μm, and preferably from 75 μm to 750 μm. When a passivation film is formed on a semiconductor substrate having a thickness of from 50 μm to 1000 μm, a passivation effect can be obtained more effectively.

The step for forming an electrode includes preferably: applying a composition for forming an electrode onto a semiconductor substrate to form a layer of the composition (composition layer) for forming an electrode; and sintering the layer of the composition for forming an electrode to form an electrode. By the above, an electrode can be formed on a semiconductor substrate with high productivity by a simple method. Further, since an electrode can be formed before a passivation film is formed, there can be a broad range of options for electrode formation conditions and an electrode with a desired characteristic can be formed efficiently.

The composition for forming an electrode may be selected appropriately according to need from the compositions used ordinarily. Specific examples of a composition for forming an electrode include a silver paste, an aluminum paste, and a copper paste, supplied commercially from various companies for a photovoltaic cell electrode.

There is no particular restriction on a method for forming a composition layer for forming an electrode on a semiconductor substrate using a composition for forming an electrode, and the method may be selected appropriately from known coating methods, etc. according to need. Specific examples thereof include a printing method such as screen printing, and an ink jet method. Further, when a masking material, an etching method, or the like is also used, a dipping method, a spin coating method, brush coating, a spray method, a doctor blade method, a roll coater method, brush coating, an ink jet method, etc. may be used.

There is no particular restriction on an application amount of a composition for forming an electrode onto a semiconductor substrate, and the amount may be selected appropriately according to the shape of an electrode to be formed, or the like. Further, there is no particular restriction on the shape of an electrode to be formed, and the shape may be selected appropriately according to an object.

A composition layer for forming an electrode formed on a semiconductor substrate is sintered to form an electrode. Sintering conditions are selected appropriately depending on the composition for forming an electrode. For example, the sintering may be carried out at a temperature of from 600° C. to 850° C. for 1 second to 60 seconds.

A composition for forming a semiconductor substrate passivation film containing an organic aluminum compound is applied onto a surface of the semiconductor substrate, on which the electrode has been applied, to form a composition layer in a desired shape. There is no particular restriction on the shape of a composition layer formed with the composition for forming a semiconductor substrate passivation film, and the same may be selected appropriately according to need. Among others, a process step for applying the composition to a region in which an electrode is not formed on the semiconductor substrate, namely to a region in which the semiconductor substrate does not contact an electrode, is preferable. According to the step, increase in contact resistance of an electrode can be suppressed, and a passivation film can be formed by a simpler method. Details of the composition for forming a semiconductor substrate passivation film will be described below.

There is no particular restriction on a method for forming a composition layer on a semiconductor substrate by applying a composition for forming a passivation film, insofar as a composition layer can be formed in a desired shape, and a method may be selected appropriately according to need from known coating methods. Specific examples include a printing method such as screen printing, and an ink jet method. Meanwhile, when a masking material, an etching method, or the like is used in a combination, a method such as a dipping method, a spin coating method, brush coating, a spray method, a doctor blade method, or a roll coater method may be also used.

There is no particular restriction on the application amount of the composition for forming a passivation film on a semiconductor substrate. It is preferable, for example that the amount may be selected appropriately so as to make the film thickness of a passivation film to be formed to the film thickness described below.

The production method preferably includes additionally: applying an alkali aqueous solution onto a semiconductor substrate before the formation of a composition layer. In other words, it is preferable that a surface of a semiconductor substrate is washed with an alkali aqueous solution before the composition for forming a passivation film is applied onto the semiconductor substrate. By washing with an alkali aqueous solution, an organic substance, a particle, or the like existing on a surface of a semiconductor substrate can be removed, and a passivation effect is further improved.

Examples of a washing method with an alkali aqueous solution include a generally known RCA clean. For example, a semiconductor substrate is dipped in a mixed solution of ammonia water and hydrogen peroxide water and treated at a temperature of from 60° C. to 80° C. for removing and washing away an organic substance, a particle, or the like.

The washing duration is preferably from 10 seconds to 10 minutes, and more preferably from 30 seconds to 5 minutes.

A passivation film can be formed on a semiconductor substrate by forming a heat-treated product layer derived from the composition layer on a semiconductor substrate by heat-treating a composition layer formed with a composition for forming a passivation film.

There is no particular restriction on heat treatment conditions of a composition layer, insofar as an organic aluminum compound contained in a composition layer can be converted to aluminum oxide (Al₂O₃) as a heat-treated product. Especially, such heat treatment conditions as are suitable for forming an amorphous Al₂O₃ layer not having a specific crystal structure, are preferable. When a semiconductor substrate passivation film is formed of an amorphous Al₂O₃ layer, a negative charge can be retained more effectively on a semiconductor substrate passivation film, so as to develop a better passivation effect. The heat treatment step may be divided to a drying step and an annealing step. Although a passivation effect does not appear yet after a drying step, a passivation effect appears after an annealing step. More specifically, the annealing temperature is preferably from 400° C. to 900° C., and more preferably from 450° C. to 800° C. Meanwhile, the annealing time may be selected appropriately according to the annealing temperature, etc. It may be, for example, from 0.1 hour to 10 hours, and preferably from 0.2 hour to 5 hours.

There is no particular restriction on the film thickness of a passivation film produced by the production method, and it may be selected appropriately according to an object. For example, the film thickness is preferably from 5 nm to 50 μm, more preferably from 10 nm to 30 μm, and further preferably from 15 nm to 20 μm.

The film thickness of a formed passivation film is measured in a usual manner using a stylus step surface profiler (e.g. from Ambios Technology, Inc.).

There is no particular restriction on the shape of a passivation film, and it may be in a desired shape according to need. A passivation film may be formed all over a surface of a semiconductor substrate, or only in a partial region.

The production method of a semiconductor substrate provided with a passivation film may additionally include a step for drying a composition layer formed with the composition for forming a passivation film before the formation of a passivation film and after the application of the composition for forming a passivation film. By drying a composition layer, a passivation film having a uniform passivation effect can be formed.

There is no particular restriction on the step for drying a composition layer, insofar as a solvent contained in a composition for forming a passivation film can be removed at least partly. The drying treatment may be, for example, a drying treatment of from 30° C. and 250° C. for from 1 minute to 60 minutes, and preferably a drying treatment of from 40° C. to 220° C. for from 3 minutes to 40 minutes. The drying treatment may be carried out at normal pressure or under a reduced pressure.

Further, in the production method according to the invention, a passivation film may be formed on a semiconductor substrate prior to the formation of an electrode. In this case, an electrode is formed preferably under a condition in which aluminum oxide formed as a passivation film is not changed from an amorphous state to a crystalline state. Specifically, the production method may be as follows.

A composition layer is formed in a desired shape by applying the composition for forming a passivation film containing an organic aluminum compound on a semiconductor substrate. There is no particular restriction on the shape of the composition layer formed with the composition for forming a passivation film, and the shape may be selected appropriately according to need. Among others, a step of applying the composition selectively to a region other than a region in which an electrode is to be formed on the semiconductor substrate, is preferable, and a step for applying the composition selectively to a region other than a region in which the semiconductor substrate and an electrode are to get in contact, is more preferable. By the above means, an electrode can be formed in a desired shape after a passivation film has been formed. Details of the composition for forming a passivation film are described below.

There is no particular restriction on a method for forming a composition layer on a semiconductor substrate by applying the composition for forming a passivation film, insofar as a composition layer can be formed in a desired shape, and a method may be selected appropriately according to need from known coating methods, etc. Specific examples thereof include a printing method such as screen printing, and an ink jet method. Meanwhile, when a masking material, an etching method, or the like is used in a combination, a method such as a dipping method, a spin coating method, brush coating, a spray method, a doctor blade method, or a roll coater method may be also used.

There is no particular restriction on the application amount of the composition for forming a passivation film on a semiconductor substrate. It is preferable, for example, that the amount may be selected appropriately so as to make the film thickness of a passivation film to the film thickness described below.

The production method preferably includes additionally: applying an alkali aqueous solution onto a semiconductor substrate before the formation of a composition layer. In other words, it is preferable that a surface of a semiconductor substrate is washed with an alkali aqueous solution before the composition for forming a passivation film is applied onto the semiconductor substrate. By washing with an alkali aqueous solution, an organic substance, a particle, etc. can be removed and a passivation effect is further improved.

Examples of a washing method with an alkali aqueous solution include a generally known RCA clean. For example, a semiconductor substrate is dipped in a mixed solution of ammonia water and hydrogen peroxide water and treated at a temperature from 60° C. to 80° C. for removing and washing away an organic substance and a particle.

The washing duration is preferably from 10 seconds to 10 minutes, and more preferably from 30 seconds to 5 minutes.

A passivation film may be formed on a semiconductor substrate by heat-treating a composition layer formed with the composition for forming a semiconductor substrate passivation film on a semiconductor substrate to form a heat-treated product layer derived from the composition layer.

There is no particular restriction on heat treatment conditions of a composition layer, insofar as an organic aluminum compound contained in the composition layer can be converted to aluminum oxide (Al₂O₃) as a heat-treated product. Especially, such heat treatment conditions as are suitable for forming an amorphous Al₂O₃ layer not having a specific crystal structure, are preferable. When a semiconductor substrate passivation film is formed of an amorphous Al₂O₃ layer, a negative charge can be retained effectively owing to the semiconductor substrate passivation film so as to develop a better passivation effect. More specifically, the annealing temperature is preferably from 400° C. to 900° C., and more preferably from 450° C. to 800° C. Meanwhile, the annealing time may be selected appropriately according to the annealing temperature, etc. It may be, for example, from 0.1 hour to 10 hours, and preferably from 0.2 hour to 5 hours.

There is no particular restriction on the film thickness of a passivation film produced by the production method, and it may be selected appropriately according to an object. For example, the film thickness is preferably from 5 nm to 50 μm, more preferably from 10 nm to 30 μm, and further preferably from 15 nm to 20 μm. In this regard, the film thickness of a formed passivation film is measured in a usual manner using a stylus step surface profiler (e.g. from Ambios Technology, Inc.).

The step of forming an electrode on a semiconductor substrate preferably includes: applying a composition for forming an electrode onto a semiconductor substrate to form a composition layer for forming an electrode; and sintering the composition layer for forming an electrode to form an electrode. The step of forming a composition layer for forming an electrode is preferably a step of applying a composition for forming an electrode to a region on a semiconductor substrate, in which at least a passivation film has not been formed.

The composition for forming an electrode may be selected appropriately according to need from those used ordinarily. Specific examples of a composition for forming an electrode include a silver paste, an aluminum paste, and a copper paste, supplied commercially from various companies for a photovoltaic cell electrode.

There is no particular restriction on a method for forming a composition layer for forming an electrode on a semiconductor substrate, insofar as it can be formed in a desired shape, and a method may be selected appropriately according to need from known coating methods. Specific examples include a printing method such as screen printing, and an ink jet method. Meanwhile, when a masking material, an etching method, or the like is used in a combination, a method such as a dipping method, a spin coating method, brush coating, a spray method, a doctor blade method, or a roll coater method may be also used.

There is no particular restriction on the application amount of the composition for forming an electrode on a semiconductor substrate, and the amount may be selected appropriately according to the shape of an electrode, or the like. The production method preferably includes additionally: applying an alkali aqueous solution onto a semiconductor substrate before the formation of a composition layer.

The composition layer for forming an electrode formed on a semiconductor substrate is sintered to form an electrode. Preferably, sintering conditions are selected appropriately depending on the composition for forming an electrode to be used, to the extent that aluminum oxide formed as a passivation film is not changed from an amorphous state to a crystalline state. For example, by sintering at a temperature of from 600° C. and 850° C. for 1 second to 60 seconds, conversion to a crystalline state does not occur substantially.

Further, in a production method according to the invention, a composition layer for forming an electrode may be formed by applying the composition for forming an electrode onto a semiconductor substrate after the application of the composition for forming a passivation film onto a semiconductor substrate prior to the formation of an electrode, and performing a drying treatment with an object of removing a solvent, etc., but before the formation of a passivation film by annealing the composition layer. In this case, a step of forming an electrode by sintering a composition layer for forming an electrode, and a step for forming a passivation film by heat-treating a composition layer for forming a passivation film may be performed in either order, or the two may be performed simultaneously.

A semiconductor substrate provided with a passivation film produced by the production method may be applied to a photovoltaic cell element, a light-emitting diode device, etc. When the same is applied, for example, to a photovoltaic cell element, a photovoltaic cell element superior in conversion efficiency can be obtained.

Next, a composition for forming a passivation film applicable to the production method will be described.

The composition for forming a passivation film contains at least one organic aluminum compound. It is preferable that the composition further contains at least one resin, and more preferable that the composition contains at least one organic aluminum compound represented by the following General Formula (I) and at least one resin. The composition for forming a passivation film may contain, if necessary, additionally another component.

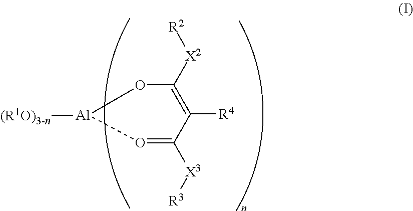

In General Formula (I), R¹'s each independently represent an alkyl group having 1 to 8 carbon atoms; n represents an integer of from 0 to 3; X² and X³ each independently represent an oxygen atom or a methylene group; and R², R³ and R⁴ each independently represent a hydrogen atom or an alkyl group having 1 to 8 carbon atoms. In this regard, when any of R¹ to R⁴, X², and X³ exists in plurality, the groups existing in plurality and expressed by the same symbol may be the same as or different from each other.

When a composition for forming a passivation film contains both the specific organic aluminum compound and a resin, the composition can be superior in pattern formability, such that a composition layer can be easily formed into a desired shape and therefore a passivation film can be formed selectively in a desired region. Further, since the composition is composed by containing a specific organic aluminum compound, it is superior in storage stability over time.

Further, the stability of a composition for forming a passivation film can be evaluated by viscosity change with time. Specifically, the stability may be evaluated by comparing a shear viscosity (η^{°}) at a shear rate of 1.0 s⁻¹ of a composition for forming a passivation film immediately after (within 12 hours or less) the preparation thereof and a shear viscosity (η³⁰) at a shear rate of 1.0 s⁻¹ of the composition for forming a passivation film after storage at 25° C. for 30 days, and for example rated by a viscosity change rate (%) with time. The viscosity change rate (%) with time is obtained by dividing an absolute value of a difference between the shear viscosity immediately after preparation and the shear viscosity after 30 days by the shear viscosity immediately after preparation, and specifically calculated according to the formula shown below. The viscosity change rate of a composition for forming a passivation film is preferably 30% or less, more preferably 20% or less, and further preferably 10% or less.

Viscosity change rate (%)=η³⁰−η⁰|/η⁰×100 (Formula)

(Organic Aluminum Compound)

The composition for forming a passivation film preferably contains at least one organic aluminum compound represented by General Formula (I). The organic aluminum compound is a compound such as an aluminum alkoxide or an aluminum chelate, and preferably has an aluminum chelate structure in addition to an aluminum alkoxide structure. The organic aluminum compound is changed to aluminum oxide (Al₂O₃) by a heat treatment as described also in Journal of the Ceramic Society of Japan, 97 (1989) 369-399.

The inventors of the present invention consider as follows concerning the reason why a passivation film with superior passivation effect can be formed when a composition for forming a passivation film contains an organic aluminum compound represented by General Formula (I).

It can be so understood that an aluminum oxide formed by heat-treating a composition for forming a passivation film containing an organic aluminum compound with a specific structure tends to form an amorphous state and generate a defect in aluminum atoms or the like, so as to have a strong negative fixed charge near the interface with a semiconductor substrate. It is further understood that the strong negative fixed charge generates an electric field near the interface with a semiconductor substrate to decrease the concentration of minority carriers, and as the result carrier recombination speed at the interface can be suppressed, whereby a passivation film with superior passivation effect is formed.

Further, as a cause of a strong negative fixed charge, it is also conceivable that a 4-coordinated aluminum oxide layer is formed near the interface with a semiconductor substrate. In this regard, the state of a 4-coordinated aluminum oxide layer, which is a causative specie of a negative fixed charge on a semiconductor substrate surface, can be examined in terms of bonding mode by analyzing a cross-section of a semiconductor substrate by an electron energy loss spectroscopy method (EELS) with a scanning transmission electron microscope (STEM). A 4-coordinated aluminum oxide is considered to have a structure, in which the central silicon of silicon dioxide (SiO₂) is replaced isomorphously with aluminum, and it has been known that the same is formed at an interface between silicon dioxide and aluminum oxide as a negative electric charge source as in the case of zeolite or clay.

The state of formed aluminum oxide may be checked by an analysis of an X-ray diffraction (XRD) spectrum. For example, when an XRD does not show a specific diffraction pattern, it indicates an amorphous structure. Further, a negative fixed charge of aluminum oxide may be analyzed by a capacitance voltage measurement (CV) method. In this connection, a surface level density obtained by a CV method with respect to a heat-treated product layer containing aluminum oxide formed from a composition for forming a passivation film according to the invention may occasionally become higher compared to an aluminum oxide layer formed by an ALD or CVD method. However, a passivation film formed from a composition for forming a passivation film according to the invention has a large field effect so as to decrease the concentration of minority carriers and extend the surface lifetime τₛ. Consequently, the surface level density is relatively not important.

In General Formula (I), R¹'s each independently represent an alkyl group having 1 to 8 carbon atoms. An alkyl group represented by R may be in a form of straight-chain or branched chain. Specific examples of an alkyl group represented by R¹ include a methyl group, an ethyl group, a propyl group, an isopropyl group, a butyl group, an isobutyl group, a sec-butyl group, a t-butyl group, a hexyl group, an octyl group, and an ethylhexyl group. Among them, an alkyl group represented by R¹ is preferably an unsubstituted alkyl group having 1 to 8 carbon atoms from viewpoints of storage stability and passivation effect, and more preferably an unsubstituted alkyl group having 1 to 4 carbon atoms.

In General Formula (I), n represents an integer of from 0 to 3. n is preferably an integer of from 1 to 3 from a viewpoint of storage stability, and more preferably 1 or 3. Meanwhile, X² and X³ each independently represent an oxygen atom or a methylene group. Preferably, at least one of X² and X³ is an oxygen atom from a viewpoint of storage stability.

In General Formula (I), R², R³ and R⁴ each independently represent a hydrogen atom or an alkyl group having 1 to 8 carbon atoms. An alkyl group represented by R², R³ or R⁴ may be in a form of straight-chain or branched chain. Specific examples of an alkyl group represented by R², R³ or R⁴ include a methyl group, an ethyl group, a propyl group, an isopropyl group, a butyl group, an isobutyl group, a sec-butyl group, a t-butyl group, a hexyl group, an octyl group, and an ethylhexyl group.

Among them, it is preferable that an alkyl group represented by R² or R³ independently represents a hydrogen atom or an unsubstituted alkyl group having 1 to 8 carbon atoms from viewpoints of storage stability and passivation effect, and more preferably a hydrogen atom or an unsubstituted alkyl group having 1 to 4 carbon atoms.

Further, R⁴ is preferably a hydrogen atom or an unsubstituted alkyl group having 1 to 8 carbon atoms from viewpoints of storage stability and passivation effect, and more preferably a hydrogen atom or an unsubstituted alkyl group having 1 to 4 carbon atoms.

From viewpoints of storage stability and passivation effect, the organic aluminum compound represented by General Formula (I) is preferably at least one selected from the group consisting of a compound in which n is 0, and R¹'s each independently represent an alkyl group having 1 to 4 carbon atoms, and a compound in which n is from 1 to 3, R¹'s each independently represent an alkyl group having 1 to 4 carbon atoms, at least one of X² and X³ is an oxygen atom, R² and R³ each independently are a hydrogen atom or an alkyl group having 1 to 4 carbon atoms, and R⁴ is a hydrogen atom or an alkyl group having 1 to 4 carbon atoms; and more preferably at least one selected from the group consisting of a compound in which n is 0, and R¹ is an unsubstituted alkyl group having 1 to 4 carbon atoms, and a compound in which n is from 1 to 3, R¹ is an unsubstituted alkyl group having 1 to 4 carbon atoms, at least one of X² and X³ is an oxygen atom, R² or R³ bonded to the oxygen atom is an alkyl group having 1 to 4 carbon atoms, and when X² or X³ is a methylene group, R² or R³ bonded to the methylene group is a hydrogen atom, and R⁴ is a hydrogen atom.

Specific examples of an aluminum trialkoxide, which is an organic aluminum compound represented by General Formula (I) wherein n is 0, include trimethoxy aluminum, triethoxy aluminum (aluminum ethylate), triisopropoxy aluminum (aluminum isopropylate), tri-sec-butoxy aluminum (aluminum sec-butyrate), mono-sec-butoxy-diisopropoxy aluminum (mono-sec-butoxy aluminum diisopropylate), tri-tert-butoxy aluminum, and tri-n-butoxy aluminum.

An organic aluminum compound represented by General Formula (I) in which n is from 1 to 3, may be prepared by mixing the aluminum trialkoxide and a compound having a specific structure having 2 carbonyl groups. Also, a commercially-supplied aluminum chelate compound may be used.

When the aluminum trialkoxide and a compound having 2 carbonyl groups are mixed, at least a part of the alkoxide groups in the aluminum trialkoxide is replaced with the compound having 2 carbonyl groups to form an aluminum chelate structure. In that event, if necessary, a solvent may be present, and a heat treatment or catalyst addition may be performed. When at least a part of the aluminum alkoxide structure is replaced to an aluminum chelate structure, the stability of an organic aluminum compound with respect to hydrolysis or polymerization reaction is improved, and the storage stability of a composition for forming a passivation film containing the same can be improved.

As a compound having a specific structure having 2 carbonyl groups, at least one selected from the group consisting of a β-diketone compound, a β-ketoester compound, and a malonic acid diester is preferable from a viewpoint of storage stability. Specific examples of the compound having a specific structure having 2 carbonyl groups include a β-diketone compound such as acetylacetone, 3-methyl-2,4-pentanedione, 2,3-pentanedione, 3-ethyl-2,4-pentanedione, 3-butyl-2,4-pentanedione, 2,2,6,6-tetramethyl-3,5-heptanedione, 2,6-dimethyl-3,5-heptanedione, or 6-methyl-2,4-heptanedione; a β-ketoester compound such as methyl acetoacetate, ethyl acetoacetate, propyl acetoacetate, isobutyl acetoacetate, butyl acetoacetate, tert-butyl acetoacetate, pentyl acetoacetate, isopentyl acetoacetate, hexyl acetoacetate, n-octyl acetoacetate, heptyl acetoacetate, 3-pentyl acetoacetate, ethyl 2-acetylheptanoate, ethyl 2-butylacetoacetate, ethyl 4,4-dimethyl-3-oxovalerate, ethyl 4-methyl-3-oxovalerate, ethyl 2-ethylacetoacetate, ethyl hexylacetoacetate, methyl 4-methyl-3-oxovalerate, isopropyl acetoacetate, ethyl 3-oxohexanoate, ethyl 3-oxovalerate, methyl 3-oxovalerate, methyl 3-oxohexanoate, ethyl 2-methylacetoacetate, ethyl 3-oxoheptanoate, methyl 3-oxoheptanoate, or methyl 4,4-dimethyl-3-oxovalerate; and a malonic acid diester, such as dimethyl malonate, diethyl malonate, dipropyl malonate, diisopropyl malonate, dibutyl malonate, di-tert-butyl malonate, dihexyl malonate, tert-butyl ethyl malonate, diethyl methylmalonate, diethyl ethylmalonate, diethyl isopropylmalonate, diethyl butylmalonate, diethyl sec-butylmalonate, diethyl isobutylmalonate, or diethyl 1-methylbutylmalonate.

When the organic aluminum compound has an aluminum chelate structure, there is no particular restriction on the number of aluminum chelate structures, insofar as it is from 1 to 3. Among others, 1 or 3 is preferable from a viewpoint of storage stability. The number of aluminum chelate structures may be regulated by, for example, changing appropriately the mixing ratio of the aluminum trialkoxide to the compound having 2 carbonyl groups. Further, a compound having a desired structure may be selected from commercially-supplied aluminum chelate compounds.

Among organic aluminum compounds represented by General Formula (I), specifically, use of an organic aluminum compound in which n is from 1 to 3 is preferable from viewpoints of reactivity during a heat treatment and storage stability as a composition. The use of at least one selected from the group consisting of aluminum ethyl acetoacetate diisopropylate, aluminum tris(ethyl acetoacetate), aluminum monoacetyl acetonate bis(ethyl acetoacetate), and aluminum tris(acetyl acetonate) is more preferable, and the use of aluminum ethyl acetoacetate diisopropylate is further preferable.

The presence of an aluminum chelate structure in the organic aluminum compound may be confirmed by an analysis method used ordinarily. For example, it may be confirmed by using an infrared spectrum, a nuclear magnetic resonance spectrum, a melting point, or the like.

The content of the organic aluminum compound to be contained in the composition for forming a passivation film may be selected appropriately according to need. The content of the organic aluminum compound in the composition for forming a passivation film may be from 1 mass % to 70 mass %, preferably from 3 mass % to 60 mass %, more preferably from 5 mass % to 50 mass %, and further preferably from 10 mass % to 30 mass %, from viewpoints of storage stability and passivation effect.

The organic aluminum may be liquid or solid, without any particular restriction. From viewpoints of passivation effect and storage stability, the uniformity of a passivation film to be formed is improved and a desired passivation effect can be stably obtained, insofar as the aluminum compound is superior in stability at normal temperature, and solubility or dispersibility.

(Resin)

The composition for forming a passivation film preferably contains at least one resin. By containing a resin, a composition layer, which is formed by applying the composition for forming a passivation film on to a semiconductor substrate, can acquire improved shape stability, so that a passivation film can be formed more selectively in a desired shape in a region in which the composition layer has been formed.

There is no particular restriction on the kind of resin. Among others, a resin of which viscosity may be adjusted into a range suitable for forming a favorable pattern when the composition for forming a passivation film is applied to a semiconductor substrate, is preferable. Specific examples of the resin include a poly(vinyl alcohol) resin; a poly(acrylamide) resin; a poly(vinyl amide) resin; a polyvinyl pyrrolidone resin; a poly(ethylene oxide) resin; a poly(sulfonic acid) resin; an acrylamide alkylsulfonic acid resin; cellulose; a cellulose resin such as cellulose ether, carboxymethyl cellulose, hydroxyethyl cellulose, or ethyl cellulose; gelatin and a gelatin derivative; starch and a starch derivative; a sodium alginate; xanthan and a xanthan derivative; guar and a guar derivative; scleroglucan and a scleroglucan derivative; tragacanth and a tragacanth derivative; dextrin and a dextrin derivative; a (meth)acrylic resin such as a (meth)acrylic acid resin or a (meth)acrylate resin such as an alkyl(meth)acrylate resin or a dimethyl aminoethyl(meth)acrylate resin; a butadiene resin; a styrenic resin; a siloxane resin; and a butyral resin; as well as a copolymer thereof.

Among them, a neutral resin not having an acidic or basic functional group is preferably used from viewpoints of storage stability and pattern formability, and more preferably a cellulose resin is used from a viewpoint that the viscosity and thixotropy can be easily adjusted even with a small amount.

There is no particular restriction on the molecular weight of the resin, and the molecular weight is preferably regulated appropriately according to a desired viscosity of a composition. The weight-average molecular weight of the resin is preferably from 100 to Ser. No. 10/000,000, and more preferably from 1,000 to 5,000,000, from viewpoints of storage stability and pattern formability. The weight-average molecular weight of the resin is determined by converting a molecular weight distribution measured by gel permeation chromatography using a calibration curve based on a standard polystyrene.

The resins are used singly or in a combination of two or more thereof.

The content of the resin in a composition for forming a semiconductor substrate passivation film may be selected appropriately according to need. The resin content is, for example, preferably from 0.1 mass % to 30 mass % in a composition for forming a substrate passivation film. From a viewpoint of developing thixotropy allowing easy pattern formation, the resin content is more preferably from 1 mass % to 25 mass %, further preferably from 1.5 mass % to 20 mass %, and still further preferably from 1.5 mass % to 10 mass %.

The ratio of the contents of the organic aluminum compound and the resin in the composition for forming a passivation film may be selected appropriately according to need. Among others, the ratio of the content of the resin to the content of the organic aluminum compound (resin/organic aluminum compound) is preferably from 0.001 to 1000, more preferably from 0.01 to 100, and further preferably from 0.1 to 1, from viewpoints of pattern formability and storage stability.

(Solvent)

The composition for forming a passivation film preferably contains a solvent. When the composition for forming a passivation film contains a solvent, the viscosity thereof may be adjusted more easily so that the applicability may be improved and a more uniform heat-treated product layer may be formed. There is no particular restriction on the solvent, and it may be selected appropriately according to need. Among others, a solvent which is capable of dissolving the organic aluminum compound and the resin to yield a homogeneous solution, is preferable, and a solvent containing at least one organic solvent is more preferable.

Specific examples of a solvent include a ketone solvent such as acetone, methyl ethyl ketone, methyl n-propyl ketone, methyl isopropyl ketone, methyl n-butyl ketone, methyl isobutyl ketone, methyl n-pentyl ketone, methyl n-hexyl ketone, diethyl ketone, dipropyl ketone, diisobutyl ketone, trimethyl nonanone, cyclohexanone, cyclopentanone, methyl cyclohexanone, 2,4-pentanedione, or acetonyl acetone; an ether solvent such as diethyl ether, methyl ethyl ether, methyl n-propyl ether, diisopropyl ether, tetrahydrofuran, methyl tetrahydrofuran, dioxane, dimethyldioxane, ethylene glycol dimethyl ether, ethylene glycol diethyl ether, ethylene glycol di-n-propyl ether, ethylene glycol dibutyl ether, diethylene glycol dimethyl ether, diethylene glycol diethyl ether, diethylene glycol methyl ethyl ether, diethylene glycol methyl n-propyl ether, diethylene glycol methyl n-butyl ether, diethylene glycol di-n-propyl ether, diethylene glycol di-n-butyl ether, diethylene glycol methyl n-hexyl ether, triethylene glycol dimethyl ether, triethylene glycol diethyl ether, triethylene glycol methyl ethyl ether, triethylene glycol methyl n-butyl ether, triethylene glycol di-n-butyl ether, triethylene glycol methyl n-hexyl ether, tetraethylene glycol dimethyl ether, tetraethylene glycol diethyl ether, tetraethylene glycol methyl ethyl ether, tetraethylene glycol methyl n-butyl ether, tetraethylene glycol di-n-butyl ether, tetraethylene glycol methyl n-hexyl ether, tetraethylene glycol di-n-butyl ether, propylene glycol dimethyl ether, propylene glycol diethyl ether, propylene glycol di-n-propyl ether, propylene glycol dibutyl ether, dipropylene glycol dimethyl ether, dipropylene glycol diethyl ether, dipropylene glycol methyl ethyl ether, dipropylene glycol methyl n-butyl ether, dipropylene glycol di-n-propyl ether, dipropylene glycol di-n-butyl ether, dipropylene glycol methyl n-hexyl ether, tripropylene glycol dimethyl ether, tripropylene glycol diethyl ether, tripropylene glycol methyl ethyl ether, tripropylene glycol methyl n-butyl ether, tripropylene glycol di-n-butyl ether, tripropylene glycol methyl n-hexyl ether, tetrapropylene glycol dimethyl ether, tetrapropylene glycol diethyl ether, tetrapropylene glycol methyl ethyl ether, tetrapropylene glycol methyl n-butyl ether, tetrapropylene glycol di-n-butyl ether, tetrapropylene glycol methyl n-hexyl ether, or tetrapropylene glycol di-n-butyl ether; an ester solvent such as methyl acetate, ethyl acetate, n-propyl acetate, isopropyl acetate, n-butyl acetate, isobutyl acetate, sec-butyl acetate, n-pentyl acetate, sec-pentyl acetate, 3-methoxybutyl acetate, methylpentyl acetate, 2-ethylbutyl acetate, 2-ethylhexyl acetate, 2-(2-butoxyethoxyl)ethyl acetate, benzyl acetate, cyclohexyl acetate, methylcyclohexyl acetate, nonyl acetate, methyl acetoacetate, ethyl acetoacetate, diethylene glycol methyl ether acetate, diethylene glycol monoethyl ether acetate, dipropylene glycol methyl ether acetate, dipropylene glycol ethyl ether acetate, glycol diacetate, methoxytriglycol acetate, ethyl propionate, n-butyl propionate, isoamyl propionate, diethyl oxalate, di-n-butyl oxalate, methyl lactate, ethyl lactate, n-butyl lactate, n-amyl lactate, ethylene glycol methyl ether propionate, ethylene glycol ethyl ether propionate, ethylene glycol methyl ether acetate, ethylene glycol ethyl ether acetate, propylene glycol methyl ether acetate, propylene glycol ethyl ether acetate, propylene glycol propyl ether acetate, γ-butyrolactone, or γ-valerolactone; an aprotic polar solvent such as acetonitrile, N-methyl pyrrolidinone, N-ethyl pyrrolidinone, N-propyl pyrrolidinone, N-butyl pyrrolidinone, N-hexyl pyrrolidinone, N-cyclohexyl pyrrolidinone, N,N-dimethyl formamide, N,N-dimethyl acetamide, or dimethyl sulfoxide; an alcohol solvent such as methanol, ethanol, n-propanol, isopropanol, n-butanol, isobutanol, sec-butanol, t-butanol, n-pentanol, isopentanol, 2-methylbutanol, sec-pentanol, t-pentanol, 3-methoxybutanol, n-hexanol, 2-methyl pentanol, sec-hexanol, 2-ethylbutanol, sec-heptanol, n-octanol, 2-ethylhexanol, sec-octanol, n-nonylalcohol, n-decanol, sec-undecyl alcohol, trimethylnonyl alcohol, sec-tetradecyl alcohol, sec-heptadecyl alcohol, phenol, cyclohexanol, methyl cyclohexanol, benzyl alcohol, ethylene glycol, 1,2-propylene glycol, 1,3-butylene glycol, diethylene glycol, dipropylene glycol, triethylene glycol, or tripropylene glycol; a glycol monoether solvent such as ethylene glycol monomethyl ether, ethylene glycol monoethyl ether, ethylene glycol monophenyl ether, diethylene glycol monomethyl ether, diethylene glycol monoethyl ether, diethylene glycol mono-n-butyl ether, diethylene glycol mono-n-hexyl ether, ethoxytriglycol, tetraethylene glycol mono-n-butyl ether, propylene glycol monomethyl ether, dipropylene glycol monomethyl ether, dipropylene glycol monoethyl ether, or tripropylene glycol monomethyl ether; terpene solvents such as a pinene such as α-pinene or β-pinene, a terpinene such as α-terpinene, a terpineol such as α-terpineol, myrcene, allo-ocimene, limonene, dipentene, terpineol, carvone, ocimene, or phellandrene; and water. The solvents may be used singly or in a combination of two or more thereof.

Among others, from viewpoints of applicability to a semiconductor substrate and pattern formability, the solvent preferably contains at least one selected from the group consisting of a terpene solvent, an ester solvent and an alcohol solvent, and more preferably at least one selected from the group consisting of a terpene solvent.

The content of a solvent in a composition for forming a passivation film is decided considering applicability, pattern formability, and storage stability. The content of a solvent in a composition for forming a passivation film is preferably, for example, from 5 mass % to 98 mass %, and more preferably from 10 mass % to 95 mass %, from viewpoints of applicability and pattern formability of the composition.

From a viewpoint of storage stability, it is preferable that in the composition for forming a passivation film, contents of an acidic compound and a basic compound are respectively 1 mass % or less, and more preferably 0.1 mass % or less, with respect to the composition for forming a passivation film.

Examples of the acidic compound include a Bronsted acid and a Lewis acid. Specific examples thereof include an inorganic acid such as hydrochloric acid or nitric acid, and an organic acid such as acetic acid. Examples of the basic compound include a Bronsted base and a Lewis base. Specific examples thereof include an inorganic base such as an alkali metal hydroxide or an alkaline earth metal hydroxide, and an organic base such as a trialkylamine or pyridine.

There is no particular restriction on the viscosity of the composition for forming a passivation film, and it may be selected appropriately depending on an application method onto a semiconductor substrate or the like. It may be, for example, from 0.01 Pa·s to 10,000 Pa·s. From a viewpoint of pattern formability, it is preferably from 0.1 Pa·s to 1,000 Pa·s. The viscosity is measured using a rotational shearing viscometer at 25° C. at a shear rate of 1.0 s⁻¹.

There is no particular restriction on the shear viscosity of the composition for forming a passivation film. From a viewpoint of pattern formability, a thixotropic ratio (η₁/η₂) calculated by dividing a shear viscosity η₁ at a shear rate of 1 s⁻¹ by a shear viscosity η₂ at a shear rate of 10 s⁻¹ is preferably from 1.05 to 100, and more preferably from 1.1 to 50. The shear viscosity is measured using a rotational shearing viscometer equipped with a cone-plate (diameter 50 mm, cone angle 1°) at a temperature of 25° C.

There is no particular restriction on a production method of the composition for forming a semiconductor substrate passivation film. The composition may be produced, for example, by mixing an organic aluminum compound and a resin, as well as, if necessary, a solvent by a mixing method ordinarily used. The resin may be dissolved in a solvent in advance and then mixed with the organic aluminum compound to produce a composition.

Further, the organic aluminum compound may be prepared by mixing an aluminum alkoxide and a compound which is capable of forming a chelate with aluminum. In this case, a solvent may appropriately be used or a heat treatment may be conducted. The thus prepared organic aluminum compound may be mixed with the resin or a solution containing the resin to produce a composition for forming a passivation film.

Components and the contents thereof in the composition for forming a passivation film may be examined by a thermal analysis such as TG/DTA, a spectroscopic analysis such as NMR or IR, a chromatographic analysis such as HPLC or GPC, or the like.

<Semiconductor Substrate Provided with Passivation Film>

A semiconductor substrate provided with a passivation film according to the invention is produced by the production method of the present invention, and includes a semiconductor substrate and a heat-treated product layer of a composition for forming a passivation film containing an organic aluminum compound, which is arranged on the semiconductor substrate. The semiconductor substrate provided with a passivation film exhibits a superior passivation effect owing to the presence of a passivation film, which is a layer composed of a heat-treated product of the composition for forming a passivation film.

The semiconductor substrate provided with a passivation film may be applied to a photovoltaic cell element, a light-emitting diode device, etc. When the same is applied, for example, to a photovoltaic cell element, a photovoltaic cell element superior in conversion efficiency can be obtained.

<Production Method of Photovoltaic Cell Element>

A method of producing a photovoltaic cell element according to the invention includes: forming an electrode on at least one layer selected from the group consisting of a p-type layer and an n-type layer on a semiconductor substrate having a p-n junction of the p-type layer and the n-type layer; applying a composition for forming a passivation film onto one or both surfaces of the semiconductor substrate on which the electrode is formed to form a composition layer, the composition for forming a passivation film containing an organic aluminum compound; and heat-treating the composition layer to form a passivation film. The production method of a photovoltaic cell element may, if necessary, include an additional step.

By the use of the composition for forming a passivation film, a photovoltaic cell element superior in conversion efficiency and provided with a passivation film of a semiconductor substrate superior in passivation effect can be produced by a simple method. Moreover, since a passivation film of a semiconductor substrate can be formed in a desired shape on a semiconductor substrate, on which an electrode is formed, a photovoltaic cell element is superior in productivity.

The formation of an electrode in the invention may be carried out before the formation of a composition layer, or after the formation of a composition layer or formation of a passivation film. The formation of an electrode is preferably carried out before the formation of a composition layer from a viewpoint of obtaining a better passivation effect.

A step of forming an electrode on at least one layer selected from the group consisting of the p-type layer and the n-type layer may be carried out by selecting appropriately a method from ordinary methods used for forming an electrode. For example, an electrode may be formed by applying an electrode formation paste, such as a silver paste or an aluminum paste, to a desired region on a semiconductor substrate, and, if necessary, conducting sintering. Details of a production method of an electrode are described above.

A surface of a semiconductor substrate, on which the passivation film is to be provided, may be a p-type layer or an n-type layer. Among others, however, a p-type layer is preferable from a viewpoint of conversion efficiency.

Details of a method of forming a passivation film using the composition for forming a passivation film are similar to the production method of a semiconductor substrate with a passivation film as descried above, and a preferable embodiment is also the same.

There is no particular restriction on the thickness of a passivation film of a semiconductor substrate formed on the semiconductor substrate, and the same may be selected appropriately according to an object. For example, the thickness is preferably from 5 nm to 50 μm, more preferably from 10 nm to 30 μm, and further preferably from 15 nm to 20 μm.

<Photovoltaic Cell Element>

A photovoltaic cell element according to the invention is produced by the method of producing a photovoltaic cell element of the invention, and includes: a semiconductor substrate having a p-n junction of a p-type layer and an n-type layer; a passivation film which is a heat-treated product layer of the composition for forming a passivation film containing an organic aluminum compound, provided on all or a part of a surface of the semiconductor substrate; and an electrode arranged on one or more layers selected from the group consisting of the p-type layer and the n-type layer of the semiconductor substrate. The photovoltaic cell element may additionally include, if necessary, another constituent.

The photovoltaic cell element according to the invention is superior in conversion efficiency, because of presence of a passivation film formed by the production method of a photovoltaic cell element

There is no restriction on the shape or dimension of a photovoltaic cell element. For example, a square, from 125 mm to 156 mm on a side, is preferable.

Next, embodiments of the invention will be described hereinbelow referring to the drawings.

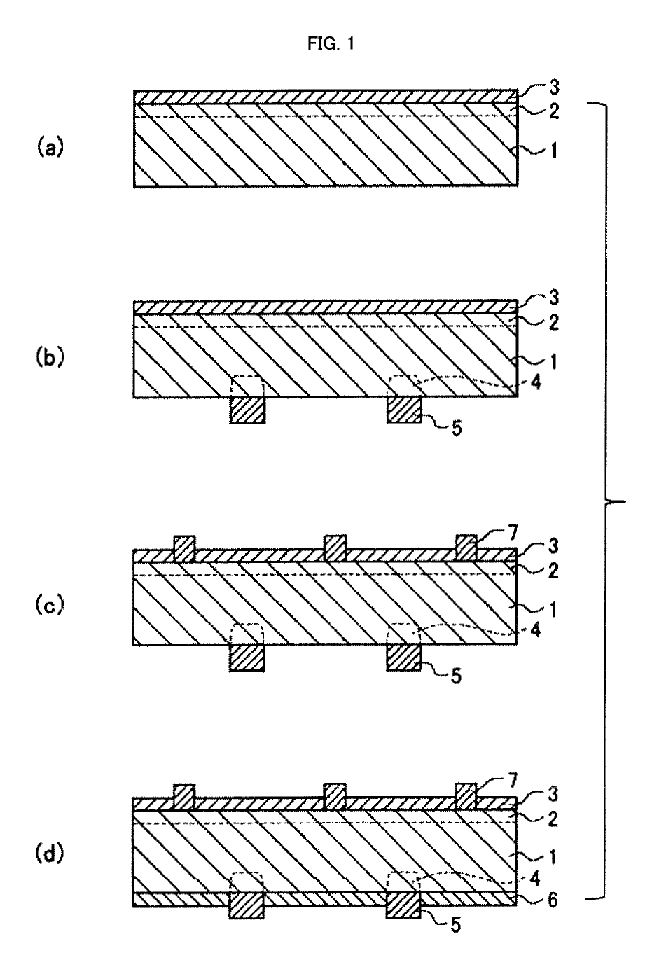

FIG. 1 is a schematic cross-sectional view of a flow diagram showing an example of a production method of a photovoltaic cell element provided with a passivation film of a semiconductor substrate according to an embodiment of the present invention. However, the flow diagram does not restrict by any means the invention.

As shown in FIG. 1(a), an n⁺-type diffusion layer 2 is formed in the vicinity of a top surface of a p-type semiconductor substrate 1, and an antireflection film 3 is formed on an outermost surface of the p-type semiconductor substrate 1. Examples of the antireflection film 3 include a silicon nitride film and a titanium oxide film. There may be another surface protective film (not illustrated) such as a silicon oxide film between the antireflection film 3 and the p-type semiconductor substrate 1. Further, a passivation film of a semiconductor substrate according to the invention may be used as a surface protective film.

Next, as shown in FIG. 1(b), a material, such as an aluminum electrode paste, for forming a back surface electrode 5 is coated onto a part of the back surface, followed by sintering, whereby back surface electrodes 5 are formed and aluminum atoms are diffused into the p-type semiconductor substrate 1 to form a p⁺-type diffusion layer 4.

Next, as shown in FIG. 1(c), an electrode-forming paste is coated on a light-receiving surface and then heat-treated to form a surface electrode 7. In a case in which an electrode-forming paste containing a glass powder having a fire-through property is used, a surface electrode 7 may be formed on the n⁺-type diffusion layer 2 through the antireflection film 3 as shown in FIG. 1(c), and an ohmic contact is attained.

Finally, as shown in FIG. 1(d), a composition for forming a passivation film is applied onto the p-type layer at the back surface, except for the region in which the back surface electrode 5 has been formed, to form a composition layer. The application may be performed, for example, by a coating method such as a screen printing. The composition layer formed on the p-type layer is then heat-treated to form a passivation film 6. A photovoltaic cell element superior in improved electric power generation efficiency can be produced by providing the passivation film 6 formed using the composition for forming a passivation film on the p-type layer at the back surface.

A photovoltaic cell element to be produced according to the production method containing process steps as shown in FIG. 1 can have a back surface electrode made of aluminum, etc. in a point contact structure, so that warping, etc. of a substrate can be mitigated. Further, by using the composition for forming a passivation film, a passivation film of a semiconductor substrate can be formed with high productivity only on a p-type layer except for a region in which an electrode has been arranged.

FIG. 1(d) shows a method of forming a passivation film only on a back surface. However, the composition for forming a passivation film may be applied also to a side surface of the semiconductor substrate 1 in addition to the back surface, and heat-treated to form a passivation film on the side surface (edge) of the semiconductor substrate 1 (not illustrated). By this means, a photovoltaic cell element with an improved electric power generation efficiency can be produced.

Further, the composition for forming a semiconductor substrate passivation film according to the invention may be coated only on a side surface and heat-treated to form a passivation film of a semiconductor substrate, without forming a passivation film of a semiconductor substrate on the back surface. The composition for forming a semiconductor substrate passivation film according to the invention is especially effective, if it is used in a place with many crystal defects such as a side surface.

In FIG. 1, an embodiment in which a passivation film is formed after an electrode is formed, is described. However, an electrode of aluminum, etc. may be formed in a desired region by vapor deposition, etc. after the formation of the passivation film.

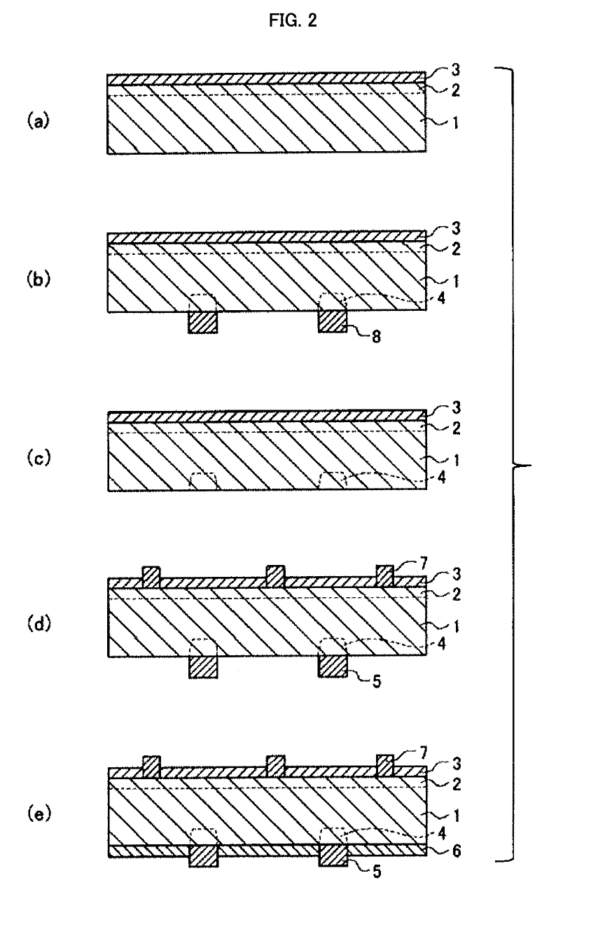

FIG. 2 is a schematic cross-sectional view of a flow diagram showing another example of a production method of a photovoltaic cell element provided with a passivation film according to an embodiment of the present invention. Specifically, FIG. 2 illustrates as cross-sectional views, a flow diagram including a step in which a p⁺-type diffusion layer is formed using an aluminum electrode paste or a composition for forming a p-type diffusion layer which is cable of forming a p⁺-type diffusion layer by a thermal diffusion treatment, and then a sintered product of the aluminum electrode paste or a heat-treated product of the composition for forming a p-type diffusion layer is removed. In this regard, examples of the composition for forming a p-type diffusion layer include a composition containing a substance containing an acceptor element and a glass component.

As shown in FIG. 2(a), an n⁺-type diffusion layer 2 is formed in the vicinity of a top surface of a p-type semiconductor substrate 1, and an antireflection film 3 is formed on a surface of the p-type semiconductor substrate 1. Examples of the antireflection film 3 include a silicon nitride film and a titanium oxide film.

Next, as shown in FIG. 2(b), a composition for forming a p-type diffusion layer is coated onto a part of the back surface, and then heat-treated to form a p⁺-type diffusion layer 4. On the p⁺-type diffusion layer 4, a heat-treated product 8 of the composition for forming a p-type diffusion layer is formed.

In this procedure, an aluminum electrode paste instead of the composition for forming a p-type diffusion layer may be used. When an aluminum electrode paste is used, an aluminum electrode 8 is formed on the p⁺-type diffusion layer 4.

Next, as shown in FIG. 2(c), the heat-treated product 8 of the composition for forming a p-type diffusion layer or the aluminum electrode 8 formed on the p⁺-type diffusion layer 4 is removed by a technique such as etching.

Next, as shown in FIG. 2(d), an electrode-forming paste is selectively coated on a part of a light-receiving surface (front surface) and a back surface, and sintered to form surface electrodes 7 on the light-receiving surface and back surface electrodes 5 on the back surface. In a case in which an electrode-forming paste containing a glass powder having a fire-through property is used as an electrode-forming paste to be applied to a light-receiving surface, a surface electrode 7 may be formed on the n⁺-type diffusion layer 2 through the antireflection film 3 as shown in FIG. 2(d), and an ohmic contact is attained.

Further, since a p⁺-type diffusion layer 4 has been formed in a region in which a back surface electrode is to be formed, the electrode-forming paste for forming a back surface electrode 5 is not limited to an aluminum electrode paste, and an electrode-forming paste which is capable of forming a lower resistance electrode, such as a silver electrode paste, may be used. From this, the electric power generation efficiency can be further enhanced.

Finally, as shown in FIG. 2(e), a composition for forming a passivation film is applied onto the p-type layer at the back surface except for the region in which the back surface electrode 5 has been formed, to form a composition layer. The application may be carried out, for example, by a coating method such as a screen printing. The composition layer formed on the p-type layer is then heat-treated to form a passivation film 6. A photovoltaic cell element superior in electric power generation efficiency can be produced by providing the passivation film 6 formed with the composition for forming a passivation film on the p-type layer of the back surface.

FIG. 2(e) shows a method of forming a passivation film only on a back surface. However, a material for forming a passivation film may be coated also to a side surface of the p-type semiconductor substrate 1 in addition to the back surface, and heat-treated to form a passivation film also on the side surface (edge) of the p-type semiconductor substrate 1 (not illustrated). By this means, a photovoltaic cell element with better electric power generation efficiency can be produced.

Further, the composition for forming a passivation film according to the invention may be applied only onto a side surface and heat-treated to form a passivation film, without forming a passivation film on a back surface. The composition for forming a passivation film according to the invention is especially effective, if it is used in a place with many crystal defects such as side surfaces.

In FIG. 2, an embodiment in which a passivation film is formed after an electrode has been formed is described. However, an electrode of aluminum, etc. may be formed in a desired region by vapor deposition, etc. after the formation of the passivation film.

Although, in the above embodiment, a case of a p-type semiconductor substrate with an n⁺-type diffusion layer formed on a light-receiving surface is described, a photovoltaic cell element may be produced even when an n-type semiconductor substrate with a p⁺-type diffusion layer formed on the light-receiving surface is used. In this case, an n⁺-type diffusion layer is formed on the back surface.

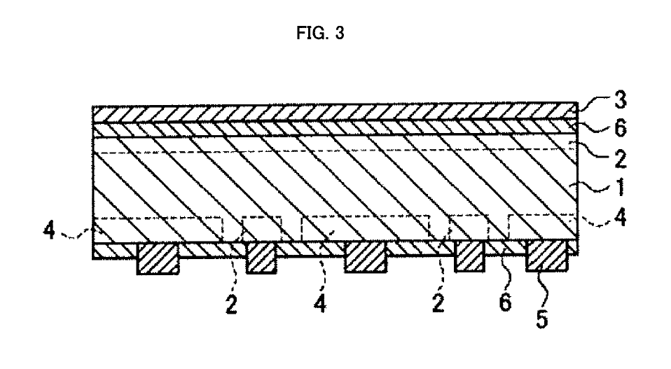

Further, the composition for forming a passivation film can be also used for forming a passivation film 6 on a light-receiving surface or a back surface of a back contact photovoltaic cell element, in which electrodes are provided only on the back surface as shown in FIG. 3.

As shown in a schematic cross-sectional view in FIG. 3, an n⁺-type diffusion layer 2 is formed in the vicinity of a top surface of a light-receiving surface of a p-type semiconductor substrate 1, and a passivation film 6 and an antireflection film 3 are formed on the surface of the p-type semiconductor substrate 1. As an antireflection film 3, a silicon nitride film, a titanium oxide film, or the like is known. Meanwhile, the semiconductor substrate passivation film 6 is formed by applying the composition for forming a passivation film according to the invention, followed by a heat treatment.

On a back surface of the p-type semiconductor substrate 1, back surface electrodes 5 are formed on a p⁺-type diffusion layer 4 and an n⁺-type diffusion layer 2 respectively, and a passivation film 6 is formed in a region of the back surface in which the electrodes are not formed.

A p⁺-type diffusion layer 4 may be formed by coating the composition for forming a p-type diffusion layer or an aluminum electrode paste in a desired region as mentioned above, followed by a heat treatment. Meanwhile, an n⁺-type diffusion layer 2 may be formed, for example, by coating a composition for forming an n-type diffusion layer, which is capable of forming an n⁺-type diffusion layer by a thermal diffusion treatment, onto a desired region, followed by a heat-treatment.

Examples of the composition for forming an n-type diffusion layer include a composition containing a substance containing a donor element and a glass component.

The back surface electrodes 5 to be arranged on the p⁺-type diffusion layer 4 and the n⁺-type diffusion layer 2 respectively may be formed with an ordinarily used electrode forming paste such as a silver electrode paste.

Meanwhile, a back surface electrode 5 to be provided on a p⁺-type diffusion layer 4 may be an aluminum electrode which is formed together with the p⁺-type diffusion layer 4 using an aluminum electrode paste.

The passivation film 6 formed on the back surface may be formed by applying the composition for forming a passivation film to a region in which a back surface electrode 5 has not been formed, followed by a sintering heat-treatment.

Further, the passivation film 6 may be formed not only on the back surface of the semiconductor substrate 1, but also on a side surface (not illustrated).

A back contact photovoltaic cell element as shown in FIG. 3 does not have an electrode on the light-receiving surface, and therefore is superior in electric power generation efficiency. Further, since a passivation film is formed in a region of the back surface, in which an electrode has not been formed, the conversion efficiency can be further improved.

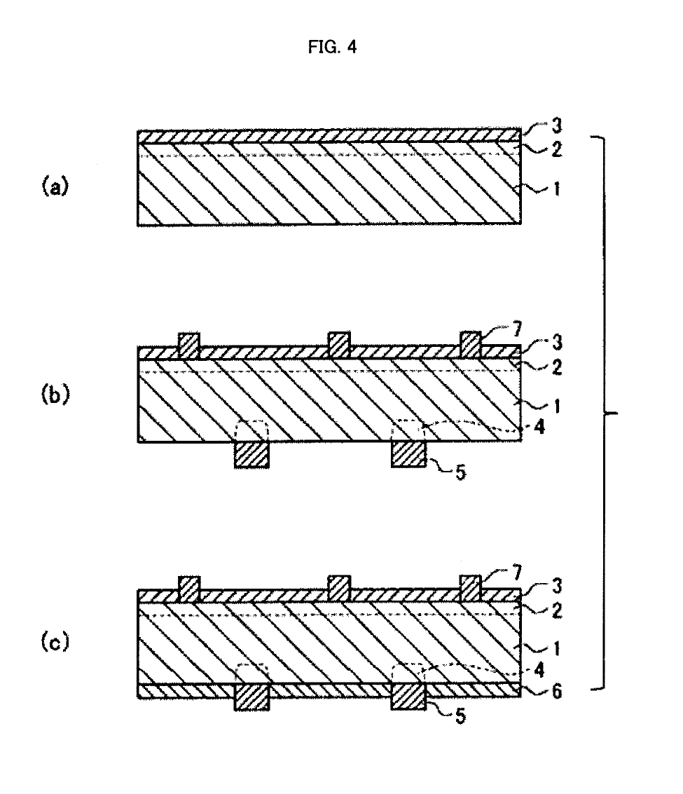

FIG. 4 shows schematic cross-sectional views of a flow diagram showing another example of a production method of a photovoltaic cell element provided with a passivation film according to an embodiment of the present invention. In FIG. 4, a passivation film is formed by forming a surface electrode 7 and a back side electrode 5 by sintering simultaneously or successively on a p-type semiconductor substrate 1 with an antireflection film 3 and an n⁺-type diffusion layer 2, and thereafter applying a composition for forming a passivation film to a region in which the electrodes have not been formed.

As shown in FIG. 4(a), an n⁺-type diffusion layer 2 is formed in the vicinity of a top surface of a p-type semiconductor substrate 1, and an antireflection film 3 is formed on an outermost surface of the p-type semiconductor substrate 1. Examples of the antireflection film 3 include a silicon nitride film and a titanium oxide film. There may be another surface protective film (not illustrated) such as a silicon oxide film between the antireflection film 3 and the p-type semiconductor substrate 1. Further, a passivation film according to the invention may be used as a surface protective film.

Next, as shown in FIG. 4(b), a material for forming a back side electrode 5 such as an aluminum electrode paste is coated on a partial region of the back surface. Further, on a light-receiving surface, an electrode forming paste is coated. Then, the substrate is sintered to form a back surface electrode 5 and also diffuse an aluminum atom into a p-type semiconductor substrate 1 for forming a p⁺-type diffusion layer 4. Simultaneously, a surface electrode 7 is formed. The surface electrodes 7 can be formed, by using an electrode forming paste containing a glass powder having a firing through property, through the antireflection film 3 achieving an ohmic contact with the n⁺-type diffusion layer 2 as illustrated in FIG. 4(b).

Finally, as shown in FIG. 4(c), a composition for forming a passivation film is applied onto the p-type layer of the back surface, except for the region in which the back surface electrode 5 has been formed, to form a composition layer. The application may be performed, for example, by screen printing. The composition layer formed on the p-type layer is then heat-treated to form a passivation film 6. A photovoltaic cell element superior in electric power generation efficiency can be produced by providing the passivation film 6 formed using the composition for forming a passivation film on the p-type layer of the back surface.

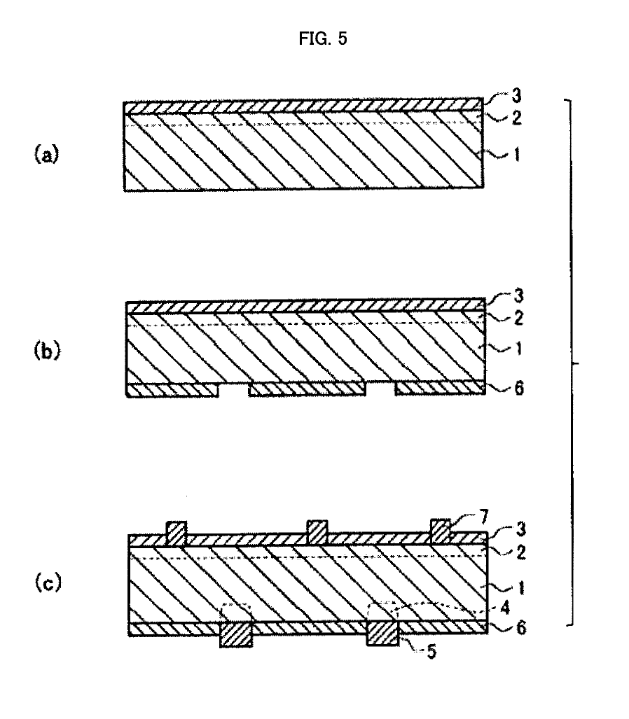

FIG. 5 shows schematic cross-sectional views of a flow diagram showing another example of a production method of a photovoltaic cell element provided with a passivation film according to an embodiment of the present invention. In FIG. 5, a composition for forming a semiconductor substrate passivation film is applied to form a composition layer prior to the formation of back surface electrodes 5.

As shown in FIG. 5(a), an n⁺-type diffusion layer 2 is formed in the vicinity of a top surface of a p-type semiconductor substrate 1, and an antireflection film 3 is formed on an outermost surface of the p-type semiconductor substrate 1. Examples of an antireflection film 3 include a silicon nitride film and a titanium oxide film. There may be another surface protective film (not illustrated) such as a silicon oxide film between the antireflection film 3 and the p-type semiconductor substrate 1. Further, a passivation film according to the invention may be used as a surface protective film.

Next, as shown in FIG. 5(d), a composition for forming a passivation film is applied onto the p-type layer of the back surface, except for the region in which a back surface electrode 5 is to be formed, to form a composition layer. The application may be performed, for example, by screen printing. The composition layer formed on the p-type layer is heat-treated to form a passivation film 6.

Further, as shown in FIG. 5(c), a material for forming a back side electrode 5, such as an aluminum electrode paste is coated on a partial region of the back surface. Further, on the light-receiving surface, an electrode forming paste is coated. By sintering these, back surface electrodes 5 are formed, and also a p⁺-type diffusion layer 4 is formed by allowing an aluminum atom to diffuse into a p-type semiconductor substrate 1. The surface electrodes 7 are also formed. The order of the coating steps of the electrode forming pastes is reversible, and both the sintering steps may be simultaneous, or the electrodes may be formed in the order of the coating steps. The surface electrodes 7 can be formed, by using an electrode forming paste for electrodes 7 containing a glass powder having a firing through property, through the antireflection film 3 achieving an ohmic contact with the n⁺-type diffusion layer 2 as illustrated in FIG. 5(c).

Although an example in which a p-type semiconductor substrate is used as a semiconductor substrate, is described above, a photovoltaic cell element superior in conversion efficiency can be produced in the same manner as above, even when an n-type semiconductor substrate is used.

<Photovoltaic Cell>

A photovoltaic cell is configured by including at least one photovoltaic cell element and a wiring material arranged on an electrode of the photovoltaic cell element. A photovoltaic cell may be, if necessary, also so configured that a plurality of photovoltaic cell elements are linked through a wiring material and sealed in a sealing material.

There is no particular restriction on the wiring material and sealing material, and they may be selected appropriately from those used ordinarily in the technical field.

There is no restriction on the size of the photovoltaic cell. It is preferably from 0.5 m² to 3 m².

### EXAMPLES

The invention will be described more specifically hereinbelow by way of examples, provided that the invention be not limited to the examples. Meanwhile, “%” is mass base, unless otherwise specified.

### Example 1

### Preparation of Composition for Forming Semiconductor Substrate Passivation Film

An organic aluminum compound solution was prepared by mixing 2.00 g of tri-sec-butoxy aluminum and 2.01 g of terpineol. Separately, 5.00 g of ethyl cellulose and 95.02 g of terpineol were mixed and stirred at 150° C. for 1 hour to prepare an ethyl cellulose solution. Then, 2.16 g of the organic aluminum compound solution and 3.00 g of the ethyl cellulose solution as obtained above were mixed to prepare a colorless, transparent solution as a composition 1 for forming a semiconductor substrate passivation film. The content of ethyl cellulose in the composition 1 for forming a semiconductor substrate passivation film was 2.9%, and the content of the organic aluminum compound was 21%.

(Formation of Passivation Film)

A mirror-surfaced single crystal p-type silicon substrate (50 mm square, thickness: 625 μm, produced by Sumco Corporation) was used as a semiconductor substrate. The silicon substrate was washed and pre-treated by immersion in an RCA cleaning liquid (FRONTIER CLEANER-A01, produced by Kanto Chemical Co., Ltd.) at 70° C. for 5 min.

Thereafter, the obtained composition 1 for forming a semiconductor substrate passivation film was applied to the pre-treated silicon substrate on all over a surface thereof by screen printing in such a manner that the film thickness after drying became 5 μm, followed by drying at 150° C. for 3 min. Next, the substrate was annealed at 550° C. for 1 hour, and left standing to cool at room temperature, thereby producing an evaluation substrate. The film thickness of the formed passivation film was 0.35 m.

(Measurement of Effective Lifetime)

The effective lifetime (μs) of the evaluation substrate obtained above was measured by a microwave reflectance photoconductivity decay method at room temperature using a lifetime measuring apparatus (WT-2000PVN, manufactured by Semilab Japan K.K.). The obtained effective lifetime in a region of the evaluation substrate in which the composition for forming a semiconductor substrate passivation film has been applied was 111 μs.

The following evaluation was conducted with respect to the obtained composition 1 for forming a passivation film. The evaluation results are shown in Table 1.

(Thixotropic Ratio)

The shear viscosity of the composition 1 for forming a semiconductor substrate passivation film prepared above was measured immediately after the preparation (within 12 hours) using a rotational shearing viscometer (MCR301, manufactured by Anton Paar GmbH) and a cone-plate (diameter 50 mm, cone angle 1°) at a temperature of 25° C. and shear rates of 1.0 s⁻¹ and 10 s⁻¹, respectively.

The shear viscosity under a shear rate of 1.0 s⁻¹ (η₁) was 16.0 Pa·s, and the shear viscosity under a shear rate of 10 s⁻¹ (η₂) was 5.7 Pa·s. The thixotropic ratio (η₁/η₂) in a case in which the shear rates were 1.0 s⁻¹ and 10 s⁻¹ was 2.8.

(Storage Stability)

The shear viscosity of the composition 1 for forming a semiconductor substrate passivation film prepared as above was measured immediately after the preparation (within 12 hours) and after storage at 25° C. for 30 days, respectively. Measurements of shear viscosity were carried out using MCR301 from Anton Paar GmbH with a cone-plate (diameter 50 mm, cone angle 1°) at a temperature of 25° C. and a shear rate of 1.0 s⁻¹.

The shear viscosity at 25° C. immediately after the preparation (η⁰) was 16.0 Pa·s, and the shear viscosity at 25° C. after storage at 25° C. for 30 days (η³⁰) was 17.3 Pa·s. As a result, a viscosity change rate (%) calculated according to the following formula was 8%.

Viscosity change rate (%)=|η³⁰−η⁰|/η⁰×100 (Formula)

### Example 2

An organic aluminum compound solution was obtained by mixing 4.79 g of tri-sec-butoxy aluminum, 2.56 g of ethyl acetoacetate, and 4.76 g of terpineol, and stirring the mixture at 25° C. for 1 hour. Separately, 12.02 g of ethyl cellulose and 88.13 g of terpineol were mixed and stirred at 150° C. for 1 hour to prepare an ethyl cellulose solution. Next, 2.93 g of the organic aluminum compound solution and 2.82 g of the ethyl cellulose solution were mixed to prepare a colorless, transparent solution as a composition 2 for forming a semiconductor substrate passivation film. The content of ethyl cellulose in the composition 2 for forming a semiconductor substrate passivation film was 5.9%, and the content of the organic aluminum compound was 21%.

A passivation film was formed on a pre-treated silicon substrate in the same manner as in Example 1 except that the composition 2 for forming a semiconductor substrate passivation film prepared above was used, and the evaluation was performed in the same manner. The effective lifetime was 144 μs.

(Thixotropic Ratio)

The shear viscosity of the composition 2 for forming a semiconductor substrate passivation film prepared above was measured immediately after the preparation (within 12 hours) using a rotational shearing viscometer (MCR301, manufactured by Anton Paar GmbH) and a cone-plate (diameter 50 mm, cone angle 1°) at a temperature of 25° C. and shear rates of 1.0 s⁻¹ and 10 s⁻¹, respectively.

The shear viscosity under a shear rate of 1.0 s⁻¹ (η₁) was 41.5 Pa·s, and the shear viscosity under a shear rate of 10 s⁻¹ (η₂) was 28.4 Pa·s. The thixotropic ratio (η₁/η₂) in a case in which the shear rates were 1.0 s⁻¹ and 10 s⁻¹ was 1.5.

(Storage Stability)

The shear viscosity of the composition 2 for forming a semiconductor substrate passivation film prepared above immediately after the preparation at a temperature of 25° C. and a shear rate of 1.0 s⁻¹ was 41.5 Pa·s, and after storage at 25° C. for 30 days was 43.2 Pa·s. Therefore, the viscosity change rate indicating storage stability was 4%.

An IR spectrum of the organic aluminum compound in the organic aluminum compound solution prepared above was obtained using EXCALIBUR FTS-3000 (manufactured by Bio-Rad Laboratories, Inc.).

As a result, an absorption near 1600 cm⁻¹ characteristic of an oxygen-carbon bond coordinated to 4-coordinated aluminum and an absorption near 1500 cm⁻¹ characteristic of a carbon-carbon bond of a 6-membered cyclic complex were observed, respectively, to confirm that an aluminum chelate was formed.

### Example 3

An organic aluminum compound solution was obtained by mixing 4.96 g of tri-sec-butoxy aluminum, 3.23 g of diethyl malonate, and 5.02 g of terpineol, and stirring the mixture at 25° C. for 1 hour. Then, 2.05 g of the obtained organic aluminum compound solution, and 2.00 g of an ethyl cellulose solution prepared in the same manner as in Example 2 were mixed to prepare a colorless, transparent solution as a composition 3 for forming a semiconductor substrate passivation film. The content of ethyl cellulose in the composition 3 for forming a semiconductor substrate passivation film was 5.9%, and the content of the organic aluminum compound was 20%.

A passivation film was formed on a pre-treated silicon substrate in the same manner as Example 1 except that the composition 3 for forming a semiconductor substrate passivation film prepared above was used, and the evaluation was performed in the same manner. The effective lifetime was 96 Vs.

(Thixotropic Ratio)

The shear viscosity of the composition 3 for forming a semiconductor substrate passivation film prepared above was measured immediately after the preparation (within 12 hours) using a rotational shearing viscometer (MCR301, manufactured by Anton Paar GmbH) and a cone-plate (diameter 50 mm, cone angle 10°) at a temperature of 25° C.

The shear viscosity under a shear rate of 1.0 s⁻¹ (η₁) was 90.7 Pa·s, the shear viscosity under a shear rate of 10 s⁻¹ (η₂) was 37.4 Pa·s, and shear viscosity under a shear rate of 100 s⁻¹ was 10.4 Pa·s. The thixotropic ratio (η₁/η₂) in a case in which the shear rates were 1.0 s⁻¹ and 10 s⁻¹ was 2.43.

(Storage Stability)

The shear viscosity of the composition 3 for forming a semiconductor substrate passivation film prepared above immediately after the preparation at a temperature of 25° C. and a shear rate of 1.0 s⁻¹ was 90.7 Pa·s, and after storage at 25° C. for 30 days was 97.1 Pa·s. Therefore, the viscosity change rate indicating storage stability was 7%.

An IR spectrum of the organic aluminum compound in the organic aluminum compound solution prepared above was obtained using EXCALIBUR FTS-3000 (manufactured by Bio-Rad Laboratories, Inc.).

As a result, an absorption near 1600 cm⁻¹ characteristic of an oxygen-carbon bond coordinated to 4-coordinated aluminum and an absorption near 1500 cm⁻¹ characteristic of a carbon-carbon bond of a 6-membered cyclic complex were observed, respectively, to confirm that an aluminum chelate was formed.

### Example 4

A passivation film was formed on the pre-treated silicon substrate in the same manner as Example 3 except that the composition 3 for forming a semiconductor substrate passivation film in Example 3 was applied onto a silicon substrate by screen printing in a form of strips with a width of 100 m at intervals of 2 mm, and the evaluation was performed in the same manner.

The effective lifetime in a region in which the composition 3 for forming a semiconductor substrate passivation film had been applied, was 90 μs. Meanwhile, the effective lifetime in a region in which the composition 3 for forming a semiconductor substrate passivation film had not been applied, was 25 μs.

### Example 5

An aluminum paste (PVG-AD-02, produced by PVG Solutions Inc.) was applied on to a silicon substrate which had been subjected to a pre-treatment in the same manner as in Example 1, by screen printing in a form of strips with a width of about 200 m at intervals of 2 mm, followed by sintering at 400° C. for 10 sec, at 850° C. for 10 sec, and at 650° C. for 10 sec, to thereby form an aluminum electrode with an thickness of 20 m.

Next, the composition 3 for forming a semiconductor substrate passivation film prepared above was applied only to a region in which an aluminum electrode had not been formed, by screen printing, and then dried at 150° C. for 3 min. Then, the substrate was annealed at 550° C. for 1 hour and left standing at room temperature to cool to form a passivation film, thereby producing an evaluation substrate.

The effective lifetime in a region in which the passivation film had been formed, was 90 μs. Further, no foreign substance originated from the composition 3 for forming a passivation film was observed on a surface of the aluminum electrode.

### Example 6

A 10% ethyl cellulose solution was prepared by mixing 100.02 g of ethyl cellulose and 400.13 g of terpineol, and stirring the mixture at 150° C. for 1 hour. Separately, 9.71 g of aluminum ethylacetoacetate diisopropylate (trade name: ALCH, produced by Kawaken Fine Chemicals Co., Ltd.) and 4.50 g of terpineol were mixed. To this mixture, 15.03 g of the 10% ethyl cellulose solution was mixed to prepare a colorless, transparent solution as a composition 6 for forming a passivation film. The content of ethyl cellulose in the composition 6 for forming a passivation film was 5.1%, and the content of the organic aluminum compound was 33.2%.

A passivation film was formed on a pre-treated silicon substrate in the same manner as Example 1 except that the composition 6 for forming a passivation film prepared above was used, and the evaluation was performed in the same manner. The effective lifetime was 121 μs.

(Thixotropic ratio) The shear viscosity of the composition 6 for forming a passivation film prepared above was measured in the same manner as above. The shear viscosity immediately after the preparation (within 12 hours) was measured by a rotational shearing viscometer (MCR301, manufactured by Anton Paar GmbH) and a cone-plate (diameter 50 mm, cone angle 1°) at a temperature of 25° C., and shear rates of 1.0 s⁻¹ or 10 s⁻¹, respectively.

The shear viscosity under a shear rate of 1.0 s⁻¹ (η₁) was 81.0 Pa·s, and the shear viscosity under a shear rate of 10 s⁻¹ (η₂) was 47.7 Pa·s. The thixotropic ratio (η₁/η₂) in a case in which the shear rates were 1.0 s⁻¹ and 10 s⁻¹ was 1.7.

(Storage Stability)

The shear viscosity of the composition 6 for forming a passivation film prepared above immediately after the preparation at a temperature of 25° C., and a shear rate of 1.0 s⁻¹ was 81.0 Pa·s, and after storage at 25° C. for 30 days was 80.7 Pa·s. Therefore, the viscosity change rate indicating storage stability was 0.4%.

(Print Smearing)

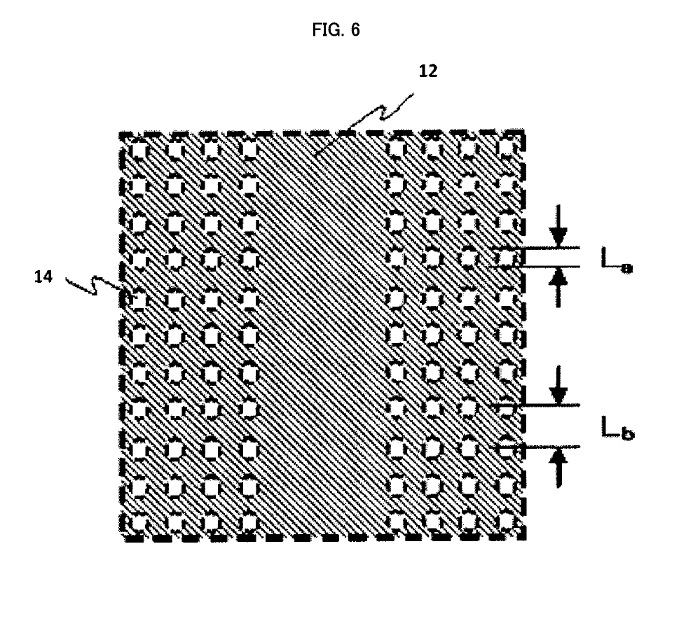

Evaluation of print smearing was performed by forming a pattern using the thus-prepared composition 6 for forming a passivation film on a silicon substrate by screen printing, and comparing a pattern shape immediately after the printing with a pattern shape after a heat treatment. For screen printing, a screen mask plate having an opening pattern reverse to a screen mask plate for forming an electrode shown in FIG. 6 having circular-dot-shaped openings 14 and non-openings 12, was used (namely a plate with non-openings corresponding to the dot-shaped openings 14 in FIG. 6). In the screen mask plate shown in FIG. 6, the dot diameter La of the dot-shaped openings 14 is 368 μm, and the dot interval Lb is 0.5 mm. In this regard, print smearing means a phenomenon, in which a composition layer formed with a composition for forming a passivation film printed on a silicon substrate expands in a planar direction of the silicon substrate compared to a used plate.

Specifically, a passivation film was formed as follows. The composition 6 for forming a passivation film prepared above was applied by a printing method to the entire surface of the regions corresponding to the non-openings 12 in FIG. 6. Then, the silicon substrate applied with the composition 6 for forming a passivation film was heated at 150° C. for 3 min to evaporate a solvent for drying, thereby forming a composition layer. Next, the silicon substrate provided with the composition layer was annealed at a temperature of 700° C. for 10 min, and then left standing at room temperature to cool, thereby forming a passivation film. The film thickness of the formed passivation film was 0.55 μm.

Evaluation of print smearing was performed by measuring the diameter of a dot-shaped opening in a passivation film formed on a substrate after the heat treatment, namely the diameter of an opening as a region corresponding to the opening 14 in FIG. 6, where a passivation film was not formed. For a measurement, 10 diameters of the openings were measured and the mean value thereof was calculated as the diameter of the opening after the heat treatment. Print smearing was rated as A, when the decrease rate of a diameter of the opening after the heat treatment with respect to the dot diameter (La) immediately after the printing (368 μm) was less than 10%; B, when the same was not less than 10% but less than 30%, and C, when the same was not less than 30%. In the case, in which the rating was A or B, the composition for forming a passivation film is acceptable.

The composition 6 for forming a passivation film obtained above was rated as A with respect to print smearing.

(Electrode Formability)

The composition 6 for forming a passivation film obtained above was printed by a screen printing method over the entire surface of the regions corresponding to the non-openings 12 on a silicon substrate. Then, the silicon substrate applied with the composition 6 for forming a passivation film was heated at 150° C. for 3 min to evaporate a solvent for drying. Next, the substrate was annealed at a temperature of 550° C. for 10 min, and then left standing at room temperature to cool, thereby forming a passivation film. The thickness of the formed passivation film was 0.57 μm.

Further, a commercially-supplied aluminum electrode paste (PVG-AD-02, manufactured by PVG Solutions Inc.) was applied over the entire surface of the silicon substrate, on which the passivation was formed, by a screen printing method. On this occasion, print conditions of the aluminum electrode paste were adjusted appropriately, so that the film thickness of a back side collector electrode after sintering became 30 μm. After printing the electrode paste, the substrate was heated at a temperature of 150° C. for 5 min to evaporate a solvent for drying.

Then, sintering was performed in a tunnel furnace (single lane conveyance W/B tunnel furnace, manufactured by Noritake Co., Limited) in the air atmosphere under the conditions of a maximum sintering temperature of 800° C., and a retention time of 10 sec, thereby forming an electrode.

Conditions of the formed aluminum electrode at a dot-shaped opening, in which a passivation film was not formed, on a silicon substrate were examined. Specifically, a cross-section corresponding to a dot diameter of a dot-shaped opening of the silicon substrate provided with the aluminum electrode was observed using a scanning electron microscope (XL30, manufactured by Philips International B.V.). The quotient (%) of the total length of an edge, on which the silicon substrate and the aluminum electrode contacted directly each other in an observed cross-section divided by a dot diameter was defined as a contact ratio, and electrode formability was rated according to the following evaluation criteria. The electrode formability of the composition 6 for forming a passivation film was rated as A.

### —Evaluation Criteria—

A: The contact ratio between a silicon substrate and an aluminum electrode was 90% or higher.

B: The contact ratio between a silicon substrate and an aluminum electrode was 70% or higher and less than 90%

C: The contact ratio between a silicon substrate and an aluminum electrode was less than 70%.

### Example 7

A composition 7 for forming a passivation film was prepared as a colorless, transparent solution by mixing 10.12 g of aluminum ethylacetoacetate diisopropylate and 25.52 g of terpineol, followed by admixing 34.70 g of a 10% ethyl cellulose solution prepared in Example 6. The content of ethyl cellulose in the composition 7 for forming a passivation film was 4.9%, and the content of the organic aluminum compound was 14.4%.

A passivation film was formed on a pre-treated silicon substrate in the same manner as in Example 1 except that the composition 7 for forming a passivation film prepared above was used, and the evaluation was performed in the same manner. The effective lifetime was 95 μs.

Thixotropic ratio, storage stability, print smearing, and electrode formability were evaluated in the same manner as above with respect to the composition 7 for forming a passivation film prepared above. The results are shown in Table 1.

(Thixotropic Ratio)

The shear viscosity under a shear rate of 1.0 s⁻¹ (η₁) was 43.4 Pa·s, and the shear viscosity under a shear rate of 10 s⁻¹ (η₂) was 27.3 Pa·s. The thixotropic ratio (η₁/η₂) in a case in which the shear viscosities were 1.0 s⁻¹ and 10 s⁻¹ was 1.6.

(Storage Stability)

The shear viscosity of the composition 7 for forming a passivation film prepared above immediately after the preparation at a temperature of 25° C., and a shear rate of 1.0 s⁻¹ was 43.4 Pa·s, and after storage at 25° C. for 30 days was 44.5 Pa·s. Therefore, the viscosity change rate indicating storage stability was 3%.

(Print Smearing)

The composition 7 for forming a semiconductor substrate passivation film was rated as A with respect to print smearing.

(Electrode Formability)

The composition 7 for forming a semiconductor substrate passivation film was rated as A with respect to electrode formability.

### Example 8

A composition 8 for forming a semiconductor substrate passivation film was prepared as a colorless, transparent solution by mixing 5.53 g of aluminum ethylacetoacetate diisopropylate and 6.07 g of terpineol, followed by admixing 9.93 g of the 10% ethyl cellulose solution prepared in Example 6. The content of ethyl cellulose in the composition 8 for forming a semiconductor substrate passivation film was 4.6%, and the content of the organic aluminum compound was 25.7%.

A passivation film was formed on a pre-treated silicon substrate in the same manner as in Example 1 except that the composition 8 for forming a semiconductor substrate passivation film prepared above was used, and the evaluation was performed in the same manner. The effective lifetime was 110 μs.

Thixotropic ratio, storage stability, print smearing, and electrode formability were evaluated similarly as above with respect to the composition 8 for forming a passivation film prepared above. The results are shown in Table 1.

(Thixotropic Ratio)

The shear viscosity under a shear rate of 1.0 s⁻¹ (η₁) was 38.5 Pa·s, and the shear viscosity under a shear rate of 10 s⁻¹ (η₂) was 28.1 Pa·s. The thixotropic ratio (η₁/η₂) in a case in which the shear rates were 1.0 s⁻¹ and 10 s⁻¹ was 1.6.

(Storage Stability)

The shear viscosity of the composition 8 for forming a passivation film immediately after the preparation at a temperature of 25° C., and a shear rate of 1.0 s⁻¹ was 38.5 Pa·s, and after storage at 25° C. for 30 days was 39.7 Pa·s. Therefore, the viscosity change rate indicating storage stability was 3%.

(Print Smearing)

The composition 8 for forming a passivation film was rated as A with respect to print smearing.

(Electrode Formability)

The composition 8 for forming a semiconductor substrate passivation film was rated as A with respect to electrode formability.

### Example 9

A 4% ethyl cellulose solution was prepared by mixing 20.18 g of ethyl cellulose and 480.22 g of terpineol, and stirring the mixture at 150° C. for 1 hour. Then, 5.09 g of aluminum ethylacetoacetate diisopropylate, 5.32 g of the 4% ethyl cellulose solution, and 11.34 g of an aluminum hydroxide particle (HP-360, particle size (D50%): 3.2 μm, purity 99.0%, produced by Showa Denko K.K.) were mixed to prepare a composition 9 for forming a semiconductor substrate passivation film as a white suspension. The content of ethyl cellulose in the composition 9 for forming a semiconductor substrate passivation film was 1.0%, and the content of the organic aluminum compound was 23.4%.

A passivation film was formed on a pre-treated silicon substrate in the same manner as in Example 1 except that the composition 9 for forming a semiconductor substrate passivation film prepared above was used, and the evaluation was performed in the same manner. The effective lifetime was 84 μs.

Thixotropic ratio, storage stability, print smearing, and electrode formability were evaluated similarly as above with respect to the composition 9 for forming a passivation film prepared above. The results are shown in Table 1.

(Thixotropic Ratio)

The shear viscosity under a shear rate of 1.0 s⁻¹ (η₁) was 33.5 Pa·s, and the shear viscosity under a shear rate of 10 s⁻¹ (η₂) was 25.6 Pa·s. The thixotropic ratio (η₁/η₂) in a case in which the shear rates were 1.0 s⁻¹ and 10 s⁻¹ was 1.3.

(Storage Stability)

The shear viscosity of the composition 9 for forming a semiconductor substrate passivation film prepared above immediately after the preparation at a temperature of 25° C., and a shear rate of 1.0 s⁻¹ was 33.5 Pa·s, and after storage at 25° C. for 30 days was 36.3 Pa·s. Therefore, the viscosity change rate indicating storage stability was 8%.

(Print Smearing)

The composition 9 for forming a passivation film was rated as A with respect to print smearing.

(Electrode Formability)

The composition 9 for forming a semiconductor substrate passivation film was rated as A with respect to electrode formability.

### Example 10

A composition 10 for forming a semiconductor substrate passivation film was prepared as a white suspension by mixing 5.18 g of aluminum ethylacetoacetate diisopropylate, 5.03 g of a 4% ethyl cellulose solution, 2.90 g of a silicon oxide particle (AEROSIL 200, average particle size 12 nm, with a surface modified with a hydroxyl group; produced by Nippon Aerosil Co., Ltd.), and 6.89 g of terpineol. The content of ethyl cellulose in the composition 10 for forming a semiconductor substrate passivation film was 1.0%, and the content of the organic aluminum compound was 25.9%.

A passivation film was formed on a pre-treated silicon substrate in the same manner as in Example 1 except that the composition 10 for forming a semiconductor substrate passivation film prepared above was used, and the evaluation was performed in the same manner. The effective lifetime was 97 μs.

Thixotropic ratio, storage stability, print smearing, and electrode formability were evaluated similarly as above with respect to the composition 10 for forming a passivation film prepared above. The results are shown in Table 1.

(Thixotropic Ratio)

The shear viscosity of the composition 10 for forming a semiconductor substrate passivation film prepared above was measured immediately after the preparation (within 12 hours) using a rotational shearing viscometer (MCR301, manufactured by Anton Paar GmbH) and a cone-plate (diameter 50 mm, cone angle 1°) at a temperature of 25° C. and shear rates of 1.0 s⁻¹ or 10 s⁻¹, respectively.

The shear viscosity under a shear rate of 1.0 s⁻¹ (η₁) was 48.3 Pa·s, and the shear viscosity under a shear rate of 10 s⁻¹ (η₂) was 32.9 Pa·s. The thixotropic ratio (η₁/η₂) in a case in which the shear rates were 1.0 s⁻¹ and 10 s⁻¹ was 1.5.

(Storage Stability)

The shear viscosity of the composition 10 for forming a semiconductor substrate passivation film prepared above immediately after the preparation at a temperature of 25° C., and a shear rate of 1.0 s⁻¹ was 48.3 Pa·s, and after storage at 25° C. for 30 days was 50.1 Pa·s. Therefore, the viscosity change rate indicating storage stability was 4%.

(Print Smearing)

The composition 10 for forming a passivation film was rated as A with respect to print smearing.

(Electrode Formability)

The composition 10 for forming a semiconductor substrate passivation film was rated as A with respect to electrode formability.

### Comparative Example 1

A substrate for evaluation was prepared in the same manner as in Example 1 except that the composition 1 for forming a semiconductor substrate passivation film in Example 1 was not coated, and the substrate was evaluated by measuring effective lifetime. The effective lifetime was 20 μs.

### Comparative Example 2

A colorless, transparent composition C2 was prepared by mixing 2.00 g of an Al₂O₃ particle (average particle size 1 m, produced by Kojundo Chemical Lab. Co., Ltd.), 1.98 g of terpineol, and 3.98 g of an ethyl cellulose solution prepared in the same manner as in Example 2.

A passivation film was formed on a pre-treated silicon substrate in the same manner as in Example 1 except that the composition C2 prepared above was used, and the evaluation was performed in the same manner. The effective lifetime was 21 μs.

### Comparative Example 3

A colorless, transparent composition C3 was prepared by mixing 2.01 g of tetraethoxysilane, 1.99 g of terpineol, and 4.04 g of an ethyl cellulose solution prepared in the same manner as in Example 2.

A passivation film was formed on a pre-treated silicon substrate in the same manner as in Example 1 except that the composition C3 prepared above was used, and the evaluation was performed in the same manner. The effective lifetime was 23 μs.

### Comparative Example 4

A composition C4 was prepared by mixing 8.02 g of trisisopropoxyaluminum, 36.03 g of purified water, and 0.15 g of concentrated nitric acid (d=1.41), followed by stirring the mixture at 100° C. for 1 hour.

A passivation film was formed on a silicon substrate provided with an aluminum electrode in the same manner as in Example 5 except that the composition C4 prepared above was used, and the evaluation was performed in the same manner.

The effective lifetime in a region in which the passivation film was formed was 110 μs. Further, a foreign substance originated from the composition C4 for forming a semiconductor substrate passivation film was observed on a surface of the aluminum electrode.

(Storage Stability) The shear viscosity of the composition C4 for forming a semiconductor substrate passivation film prepared above, immediately after the preparation at a temperature of 25° C., and a shear rate of 1.0 s⁻¹ was 67.5 Pa·s, and after storage at 25° C. for 30 days was 36,000 Pa·s.

TABLE 1

| | | | | Shear viscosity (Pa · s) | | | | | |
|---|---|---|---|---|---|---|---|---|---|
| | | | | 1.0 s⁻¹ | | 10 s⁻¹ | | | |
| | Content (%) | | Effective | Immediately | | Immediately | | | |
| | Organic aluminum | Ethyl | lifetime | after | After | after | Thixotropic | Print | Electrode |
| | compound | cellulose | (μs) | preparation | 30 days | preparation | ratio | smearing | formability |
| Example 1 | 20.9 | 2.9 | 111 | 16.0 | 17.3 | 5.7 | 2.8 | — | — |
| Example 2 | 20.2 | 5.9 | 144 | 41.5 | 43.2 | 28.4 | 1.5 | — | — |
| Example 3 | 19.0 | 5.9 | 96 | 90.7 | 97.1 | 37.4 | 2.4 | — | — |
| Example 6 | 33.2 | 5.1 | 121 | 81.0 | 80.7 | 47.7 | 1.7 | A | A |
| Example 7 | 14.4 | 4.9 | 95 | 43.4 | 44.5 | 27.3 | 1.6 | A | A |
| Example 8 | 25.7 | 4.6 | 110 | 38.5 | 39.7 | 28.1 | 1.4 | A | A |
| Example 9 | 23.4 | 1.0 | 84 | 33.5 | 36.3 | 25.6 | 1.3 | A | A |
| Example 10 | 25.9 | 1.0 | 97 | 48.3 | 50.1 | 32.9 | 1.5 | A | A |

From the above, it is clear that a semiconductor substrate passivation film superior in passivation effect can be formed by using a composition for forming a semiconductor substrate passivation film according to the invention. Further, it is clear that a composition for forming a semiconductor substrate passivation film according to the invention is superior in storage stability. Moreover, it is clear that a semiconductor substrate passivation film can be formed in a desired shape according to a simple process when a composition for forming a semiconductor substrate passivation film according to the invention is used.

The entire contents of the disclosures by Japanese Patent Application No. 2012-001653 are incorporated herein by reference.

All the literature, patent literature, and technical standards cited herein are also herein incorporated by reference to the same extent as provided for specifically and severally with respect to an individual literature, patent literature, and technical standard to the effect that the same should be so incorporated by reference.

1. A method of producing a semiconductor substrate provided with a passivation film, the method comprising:
forming an electrode on a semiconductor substrate;
applying a composition for forming a passivation film onto a surface, on which the electrode is formed, of the semiconductor substrate to form a composition layer, the composition for forming a passivation film comprising an organic aluminum compound; and
heat-treating the composition layer to form a passivation film.

2. The method of producing a semiconductor substrate provided with a passivation film according to claim 1, wherein the composition layer formed by applying the composition for forming a semiconductor substrate passivation film is formed in a region on the semiconductor substrate in which the electrode is not formed.

3. The method of producing a semiconductor substrate provided with a passivation film according to claim 1, wherein the formation of the electrode comprises:
applying a composition for forming an electrode onto the semiconductor substrate to form a composition layer for forming an electrode; and
heat-treating the composition layer for forming an electrode.

4. The method of producing a semiconductor substrate provided with a passivation film according to claim 1, wherein the composition for forming a passivation film comprises:
a compound represented by the following General Formula (I) as the organic aluminum compound; and
a resin: 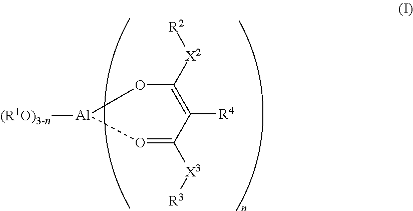
wherein, in General Formula (I), R¹'s each independently represent an alkyl group having 1 to 8 carbon atoms; n represents an integer of from 0 to 3; X² and X³ each independently represent an oxygen atom or a methylene group, and R², R³ and R⁴ each independently represent a hydrogen atom or an alkyl group having 1 to 8 carbon atoms.

5. The method of producing a semiconductor substrate provided with a passivation film according to claim 4, wherein, in General Formula (I), R¹'s each independently represent an alkyl group having 1 to 4 carbon atoms.

6. The method of producing a semiconductor substrate provided with a passivation film according to claim 4, wherein, in General Formula (I), n is an integer of from 1 to 3, and R⁴'s each independently represent a hydrogen atom or an alkyl group having 1 to 4 carbon atoms.

7. A semiconductor substrate provided with a passivation film produced by the production method according to claim 1.

8. A method of producing a photovoltaic cell element, the method comprising:
forming an electrode on at least one layer selected from the group consisting of a p-type layer and an n-type layer of a semiconductor substrate comprising a p-n junction of the p-type layer and the n-type layer;
applying a composition for forming a semiconductor substrate passivation film onto one or both surfaces of the semiconductor substrate on which the electrode is formed to form a composition layer, the composition for forming a semiconductor substrate passivation film comprising an organic aluminum compound; and
heat-treating the composition layer to form a passivation film.

9. The method of producing a photovoltaic cell element according to claim 8, wherein the composition for forming a semiconductor substrate passivation film is applied to a region on the semiconductor substrate in which the electrode is not formed.

10. The method of producing a photovoltaic cell element according to claim 8, wherein the formation of an electrode comprises:
applying a composition for forming an electrode onto the semiconductor substrate to form a composition layer for forming an electrode; and
heat-treating the composition layer for forming an electrode.

11. The method of producing a photovoltaic cell element according to claim 8, wherein the composition for forming a semiconductor substrate passivation film comprises:
a compound represented by the following General Formula (I) as the organic aluminum compound; and
a resin: 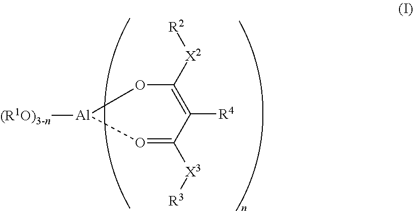
wherein, in General Formula (I), R¹'s each independently represent an alkyl group having 1 to 8 carbon atoms; n represents an integer of from 0 to 3; X² and X³ each independently represent an oxygen atom or a methylene group; and R², R³ and R⁴ each independently represent a hydrogen atom or an alkyl group having 1 to 8 carbon atoms.

12. The method of producing a photovoltaic cell element according to claim 11, wherein, in General Formula (I), R¹'s each independently represent an alkyl group having 1 to 4 carbon atoms.

13. The method of producing a photovoltaic cell element according to claim 11, wherein, in General Formula (I), n is an integer of from 1 to 3, and R⁴'s each independently represent a hydrogen atom or an alkyl group having 1 to 4 carbon atoms.

14. A photovoltaic cell element, produced by the production method according to claim 8.
